(19) United States
(12) Patent Application Publication
(10) Pub. No.: US 2016/0349320 A1
(43) Pub. Date: Dec. 1, 2016

(54) REMOTE BUS WRAPPER FOR TESTING REMOTE CORES USING AUTOMATIC TEST PATTERN GENERATION AND OTHER TECHNIQUES

(71) Applicant: QUALCOMM Incorporated, San Diego, CA (US)

(72) Inventors: Michael Laisne, Encinitas, CA (US); Bruce Cochrane, San Diego, CA (US); Fnu Praveen Ipe, San Diego, CA (US)

(21) Appl. No.: 14/794,774

(22) Filed: Jul. 8, 2015

Related U.S. Application Data
(60) Provisional application No. 62/166,670, filed on May 26, 2015.

(51) Int. Cl. G01R 31/3177; G01R 31/28

(52) U.S. Cl. CPC G01R 31/3177; G01R 31/2851

(57) ABSTRACT

A wrapper for automatic test pattern generation uses the functional bus when testing cores on an integrated circuit device. The functional bus is between the bus wrapper and the cores. During normal operation, the functional bus operates as a standard bus to communicate functional inputs and outputs between the cores and in/out of the integrated circuit device. During test operation, test signals are communicated on the functional bus. As a result, each core does not require its own wrapper; this allows the bus wrapper to reduce the area occupied by test circuitry.

### CROSS-REFERENCE TO RELATED APPLICATIONS

This application claims the benefit of U.S. Provisional App. No. 62/166,670 for “REMOTE BUS WRAPPER FOR TESTING REMOTE CORES USING AUTOMATIC TEST PATTERN GENERATION AND OTHER TECHNIQUES” filed May 26, 2015, which is incorporated herein by reference.

### BACKGROUND

The disclosure relates to automatic test pattern generation and an apparatus, methodology, and means for conditioning the logic inside the integrated circuit and for observing the response to those conditions, and in particular, to using the functional bus to communicate test signals.

Unless otherwise indicated herein, the approaches described in this section are not admitted to be prior art by inclusion in this section.

An integrated circuit device generally includes a package and a die. The die is a wafer of semiconductor material onto which functional circuits are fabricated. A collection of functional circuits that are directed toward a particular function are referred to as a core, a module, or a block. The die often has more than one core. Cores may be analog, digital, or mixed analog/digital. Example cores include a microprocessor core, a Bluetooth™ transceiver core, a digital signal processor core, a power management core, etc. The package provides protection to the die and includes input and output pins for connecting the integrated circuit device to other circuits and devices (e.g., mounted on a circuit card, circuit board, etc.).

A variety of tests may be performed on the integrated circuit device to ensure that it produces the expected outputs for a known set of inputs. These tests may be performed on the wafer (e.g., a wafer test), when the integrated circuit device has been assembled (e.g., a package test), when the integrated circuit device has been mounted on a circuit card (e.g., a mounting test), etc. Part of this testing includes automatic test pattern generation (ATPG), in which a set of defined inputs are provided to a core, and the outputs are compared to a set of reference values. Each core often has its own associated circuitry, referred to as a wrapper, for performing ATPG; when a core is designed, its designers also include in the design the associated wrapper for each core. Thus, increasing the number of cores often also results in increasing the amount of wrapper circuitry. Each wrapper may have its own test interface as well, or with additional circuitry a test interface may be shared among wrappers.

### SUMMARY

The present disclosure is directed to reducing the amount of circuitry used to perform automatic test pattern generation or for using scan input signals to control remote cores.

In one embodiment, an integrated circuit includes a plurality of cores, a bus, a functional interface, a test interface, and a bus wrapper. The bus connects between the plurality of cores. The bus selectively operates in one of a functional mode and a test mode, according to whether the integrated circuit is operating in one of the functional mode or the test mode, respectively. When the integrated circuit is operating in the functional mode, the functional interface receives a plurality of functional inputs from outside of the integrated circuit, provides the plurality of functional inputs to the bus, receives a plurality of functional outputs from the bus, and provides the plurality of functional outputs to the functional outputs outside of the integrated circuit. When the integrated circuit is operating in the test mode, the test interface receives a plurality of test inputs from outside of the integrated circuit and provides a plurality of test outputs to the outside of the integrated circuit. The bus wrapper connects between the test interface and the bus.

According to a further embodiment, in the test mode, the bus wrapper receives the plurality of test inputs from the test interface and provides the plurality of test inputs to the bus, and the plurality of cores receives the plurality of test inputs from the bus.

According to a further embodiment, in the test mode, the plurality of cores generates the plurality of test outputs from the plurality of test inputs, and provides the plurality of test outputs to the bus. In the test mode, the bus wrapper receives the plurality of test outputs from the bus.

According to a further embodiment, in the test mode, the bus wrapper receives the plurality of test inputs from the test interface and provides the plurality of test inputs to the bus. In the test mode, the plurality of cores receives the plurality of test inputs from the bus, generates the plurality of test outputs from the plurality of test inputs, and provides the plurality of test outputs to the bus. In the test mode, the bus wrapper receives the plurality of test outputs from the bus.

According to a further embodiment, in the test mode, the bus wrapper receives the plurality of test inputs from the test interface and provides the plurality of test inputs to the bus. In the test mode, the plurality of cores receives the plurality of test inputs from the bus, generates the plurality of test outputs from the plurality of test inputs, and provides the plurality of test outputs to the bus. The plurality of cores may perform a transformation on, or otherwise perform processing on, the plurality of test inputs in order to generate the plurality of test outputs. In the test mode, the plurality of cores receives the plurality of test outputs from the bus and generates a second plurality of test outputs from the plurality of test outputs.

According to a further embodiment, in the functional mode, the plurality of cores receives the plurality of functional inputs from the bus, generates the plurality of functional outputs, and provides the plurality of functional outputs to the bus.

According to a further embodiment, in the test mode, the bus is disabled prior to the bus wrapper receiving the plurality of test inputs, and the bus is enabled prior to the bus wrapper providing the plurality of test inputs to the bus.

According to a further embodiment, the bus wrapper comprises a plurality of cells. Each cell comprises a first multiplexer, a register, and a second multiplexer. The first multiplexer receives a recirculating input and a scan input, and outputs a first output corresponding to a selected one of the scan input and the recirculating input. The register receives the first output and outputs a second output corresponding to the first output, where the first multiplexer receives the second output as the recirculating input. The second multiplexer receives the second output and a functional input, and outputs a third output corresponding to a selected one of the second output and the functional input as selected by a test enable signal.

According to a further embodiment, the bus wrapper includes a pipeline. The pipeline includes a plurality of registers connected in series, where an output of one of the plurality of registers is connected to an input of another of the plurality of registers. The pipeline is loadable from the test interface in shift mode, and in capture mode the pipeline advances with each capture clock cycle. The first register in the pipeline can receive the recirculated data from the last register in the pipeline, can receive data from a fixed input state, can toggle arbitrarily between states, or can receive data from various other circuits.

According to a further embodiment, the bus wrapper includes a counter circuit that generates an enable signal and that controls the bus using the enable signal, where the enable signal controls whether the bus is enabled or not enabled.

According to a further embodiment, the bus wrapper includes a counter circuit that generates a bus clock enable signal and that controls the bus using the bus clock enable signal, where the bus clock enable signal controls whether the bus clock is enabled or not enabled.

According to a further embodiment, the integrated circuit further includes a test controller, where the test controller includes the bus wrapper. The test controller includes a data circuit, a write enable circuit, a read enable circuit, and separation logic. The data circuit stores data. The write enable circuit controls outputting the data from the data circuit to the bus. The read enable circuit controls inputting the data from the bus to the data circuit. The separation logic controls the write enable circuit and the read enable circuit.

According to a further embodiment, the bus wrapper includes a data in portion. The data in portion includes a first multiplexer, a latch, a second multiplexer, a third multiplexer, a fourth multiplexer, and a flip-flop. The first multiplexer receives a bus data input signal and an arbitrary input signal and selectively outputs a bus data latch input signal. The latch receives the bus data latch input signal and outputs a bus data latch output signal. The second multiplexer receives the bus data input signal and the bus data latch output signal, and selectively outputs a second bus data input signal. The third multiplexer receives the bus data input signal from the second multiplexer and a bus data output signal, and selectively outputs a bus data signal. The fourth multiplexer receives the bus data signal and a scan input signal, and selectively outputs a flip-flop input signal. The flip-flop receives the flip-flop input signal and outputs the bus data output signal.

According to a further embodiment, the bus wrapper includes a bus enable monitor circuit. The bus monitor circuit includes a logic circuit and a flip-flop. The logic circuit receives a bus read enable signal and a bus data enable signal, and generates an output signal. The flip-flop receives the output signal, where the flip-flop outputs a “bus on” signal that is set when the bus is in use.

According to a further embodiment, the integrated circuit further includes a master controller that controls the integrated circuit to selectively operate in one of the functional mode and the test mode.

According to a further embodiment, the integrated circuit further includes a test controller that controls the integrated circuit to selectively operate in one of a test shift mode and a test capture mode.

According to a further embodiment, the bus wrapper includes an enable portion, and the integrated circuit further comprises a test controller. The test controller is coupled to the test interface and to the bus wrapper. The test controller controls the enable portion to selectively operate in one of an output enable mode and an input enable mode. In the output enable mode, the bus wrapper provides the plurality of test inputs to the bus. In the input enable mode, the bus wrapper receives the plurality of test outputs from the bus.

According to a further embodiment, the bus wrapper includes an address portion, a data out portion, an enable portion, and a data in portion. The integrated circuit further comprises a test controller. The test controller is coupled to the test interface and to the bus wrapper. The test controller serially receives the plurality of test inputs from the test interface, and provides the plurality of test inputs to the address portion and to the data out portion. The test controller controls the enable portion to selectively operate in one of an output enable mode and an input enable mode. In the output enable mode, the address portion and the data out portion provide the plurality of test inputs to the bus, and a selected core of the plurality of cores receives the plurality of test inputs from the bus and provides the plurality of test outputs to the bus. In the input enable mode, the data in portion receives the plurality of test outputs from the bus, and the test controller serially provides the plurality of test outputs from the data in portion to the test interface.

In another embodiment, a method tests an integrated circuit. The method includes providing the integrated circuit, where the integrated circuit has a plurality of cores, a bus, a functional interface, a test interface, and a bus wrapper. The bus connects between the plurality of cores, and the bus wrapper connects between the test interface and the bus.

The method further includes selectively operating the bus in a functional mode and a test mode, according to the integrated circuit operating in one of the functional mode and the test mode.

When the integrated circuit is operating in the functional mode, the method further includes receiving, by the functional interface, a plurality of functional inputs from outside of the integrated circuit, providing, by the functional interface, the plurality of functional inputs to the bus, and receiving, by the functional interface, a plurality of functional outputs from the bus.

When the integrated circuit is operating in the test mode, the method further includes receiving, by the test interface, a plurality of test inputs from outside of the integrated circuit, and providing, by the test interface, a plurality of test outputs to the outside of the integrated circuit.

In another embodiment, an integrated circuit comprises core means for receiving a plurality of inputs, for processing the plurality of inputs, and for generating a plurality of outputs. The integrated circuit further comprises bus means for connecting between the core means, and for selectively operating in a functional mode and a test mode, according to the integrated circuit operating in one of the functional mode and the test mode. The integrated circuit further comprises functional interface means for receiving a plurality of functional inputs from outside of the integrated circuit, for providing the plurality of functional inputs to the bus means, and for receiving a plurality of functional outputs from the bus means, when the integrated circuit is operating in the functional mode. The integrated circuit further comprises test interface means for receiving a plurality of test inputs from outside of the integrated circuit, and for providing a plurality of test outputs to the outside of the integrated circuit, when the integrated circuit is operating in the test mode. The integrated circuit further comprises bus wrapper means for connecting between the test interface and the bus.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, make apparent to those of skill in the art how embodiments in accordance with the present disclosure may be practiced. In the accompanying drawings:

FIG. 1 is a block diagram of an integrated circuit 100.

FIG. 2A is a flowchart of a method 200 of testing an integrated circuit that has multiple cores.

FIG. 2B is a flowchart of a method 250 of testing an integrated circuit that has multiple cores.

FIG. 3 is a block diagram showing additional details of an integrated circuit 300 (cf. the integrated circuit 100 of FIG. 1).

FIG. 4 is a block diagram of a recirculating cell 400.

FIG. 5 is a block diagram showing how the bus wrapper 150 (see FIG. 3) may be integrated with the other scan chains in the integrated circuit.

FIG. 6. is a block diagram showing how the test controller 160 (see FIG. 3) can bypass the bus wrapper 150.

FIG. 7 is a block diagram of an integrated circuit 700 showing the clock signals that may be implemented in various embodiments.

FIG. 8 is a block diagram of an integrated circuit 800 showing more detail of the read enable operation.

FIG. 9 shows timing diagrams for the signals shown in FIG. 8. The CLK signal 820 is the scan_clock signal 821 in FIG. 8.

FIG. 10 is a block diagram of a circuit 1000 showing more details for the write enable operation.

FIG. 11 is a block diagram of a circuit 1100.

FIG. 12 is a block diagram of a circuit 1200 showing a cell for bus data.

FIG. 13 is a block diagram of an integrated circuit 1300. The circuit 1300 is an alternative arrangement for the integrated circuit 100 (see FIG. 1) or the integrated circuit 700 (see FIG. 7).

FIG. 14 is a block diagram of an integrated circuit 1400.

FIG. 15 is a block diagram of an integrated circuit 1500.

FIG. 16 is a block diagram of an integrated circuit 1600.

FIG. 17 is a block diagram of an integrated circuit 1700.

FIG. 18 shows timing diagrams for the signals shown in FIGS. 16-17.

### DETAILED DESCRIPTION

In the following description, for purposes of explanation, numerous examples and specific details are set forth in order to provide a thorough understanding of the present disclosure. It will be evident, however, to one skilled in the art that the present disclosure as expressed in the claims may include some or all of the features in these examples, alone or in combination with other features described below, and may further include modifications and equivalents of the features and concepts described herein.

The following discussion uses the term automatic test pattern generation (ATPG). In general, ATPG is a type of testing in which a set of defined inputs are provided to the registers of a core, and the outputs are compared to a set of reference values. ATPG may be contrasted with built-in self-test (BIST), in that for ATPG the test inputs originate external to the device and the test outputs are provided external to the device (e.g., using automated test equipment), whereas BIST is performed internally without an external test device. The invention may be useful for BIST operations as well, since the bus wrapper makes the bus synchronous and deterministic for test purposes. These features are useful for BIST operation.

The following discussion relates to the Institute of Electrical and Electronics Engineers (IEEE) 1149.1 standard, also referred to as the Joint Test Action Group (JTAG) standard. In general, the IEEE 1149.1 standard defines test logic that can be included in an integrated circuit to provide standardized approaches to testing the interconnections between integrated circuits once they have been assembled onto a printed circuit board or other substrate; testing the integrated circuit itself; and observing or modifying circuit activity during the component's operation (e.g., the component's normal operation in response to test inputs). The test logic consists of a boundary-scan register and other building blocks and is accessed through a Test Access Port (TAP). JTAG testing may also be referred to as boundary scan testing. However, the disclosure herein, although it may help boundary scan testing under some conditions, is broader than boundary scan testing. ATPG takes advantage of a TAP controller to put the device in a test mode. But whereas boundary scan tests the external pins, ATPG tests the internal signals. The disclosure herein also applies to other standards including IEEE 1500 and IEEE 1687. In IEEE 1149.1, the boundary scan was a scan register used to control an external input, output, or bidirectional. In IEEE 1500 this concept was extended to a wrapper boundary scan cell for purposes of testing and isolating internal blocks or cores.

The following discussion related to the terms wrapper boundary scan or wrapper boundary scan testing. In general, a boundary scan is a method for testing interconnects (wire lines) on printed circuit boards, and a wrapper boundary scan is a method for testing interconnects (wire lines) for sub-blocks inside an integrated circuit. Boundary scan is also widely used as a debugging method to watch integrated circuit pin states, measure voltage, or analyze sub-blocks inside an integrated circuit. The boundary scan architecture provides a means to test interconnects (including clusters of logic, memories, etc.) without using physical test probes; this involves the addition of at least one test cell that is connected to each pin of the device, or sub-block, and that can selectively override the functionality of that pin. Each test cell may be programmed via the JTAG scan chain to drive a signal onto a pin and thus across an individual trace on the board or signal in the integrated circuit; the cell at the destination of the board trace or sub-block signal can then be read, verifying that the board trace or sub-block signal properly connects the two pins. If the trace is shorted to another signal or if the trace is open, the correct signal value does not show up at the destination pin, indicating a defect.

The following discussion uses the term scan chain. In general, a scan chain is a chain of registers within the design that are hooked together serially in shift mode and test the circuits they belong to in capture mode. Stimulus data is first shifted into the serial scan chain. The chain is then switched from shift mode to capture mode. The data in the scan registers are then provided to a circuit as test inputs (“scan chain outputs”), and a set of outputs that are generated by the circuit (“scan chain inputs”) in response to the scan chain outputs. The scan chain is then switched back to shift mode and the result is scanned out. The output from the scan chain is then compared to a reference value in order to identify possible defects in the circuit. The term scan chain may also be used to refer to the registers or other circuit elements that store the scan chain, in which case the input and output bits or values may be referred to as the input and output test patterns. A wrapper is a special type of scan chain that wraps a sub-block. Multiple scan chains may be used during ATPG testing. The scan chain minimizes the number of device pins used for testing, and a single scan input pin and a single scan output pin are implemented for each scan chain, resulting in the scan chains being inputted and outputted serially.

The following discussion uses the term wrapper. In general, a wrapper is a set of registers that interface directly to the inputs to a core and the outputs from the core. The wrapper registers allow test inputs to be provided to the core, and for test outputs to be captured. The wrapper registers are connected sequentially, allowing for the test inputs (the scan chain outputs) to be serially clocked into the wrapper, and for the test outputs (the scan chain inputs) to be serially clocked out of the wrapper.

The following discussion uses the term bus wrapper. In general, the bus wrapper may be differentiated from the wrapper in that the bus wrapper is a set of registers that interface directly to the inputs to a bus and the outputs from the bus. As further described below, the bus is the functional bus of the device.

The following discussion uses the term test interface. In general, a test interface is a set of pins that are dedicated for test purposes. The test interface may be contrasted with the functional interface, in that the functional interface is used for the normal, standard, intended inputs and outputs of the device, whereas the test interface is used for testing. That is, if the test interface is removed, the device retains all its normal, standard, intended use functionality. In some cases, the functional interface can be reused as a test interface. In this case, a controller, state machine, registers, or some combination determine whether the specific pins associated with the interface are test pins or are functional pins.

An example of an implementation of a test interface is a test access port (TAP). The TAP is typically defined by IEEE 1149.1. Thus, the term TAP is used to describe a specific, standardized, implementation of test interface used in the JTAG standard. (When the difference is important, this specific implementation may be referred to as the IEEE 1149.1 TAP or the JTAG TAP.) The JTAG TAP has four pins and an optional fifth pin. The four pins are test data in (TDI), test data out (TDO), test clock (TCK), and test mode select (TMS). The optional fifth pin is test reset (TRST). TDI and TDO are serial input and output respectively.

The following discussion relates to the IEEE 1687 standard. In general, the IEEE 1687 standard describes a methodology for accessing instrumentation embedded within a semiconductor device, without defining the instruments or their features themselves, via the IEEE 1149.1 TAP and/or other signals. The elements of the methodology include a hardware architecture for the on-chip network connecting the instruments to the chip pins, a hardware description language to describe this network, and a software language and protocol for communicating with the instruments via this network.

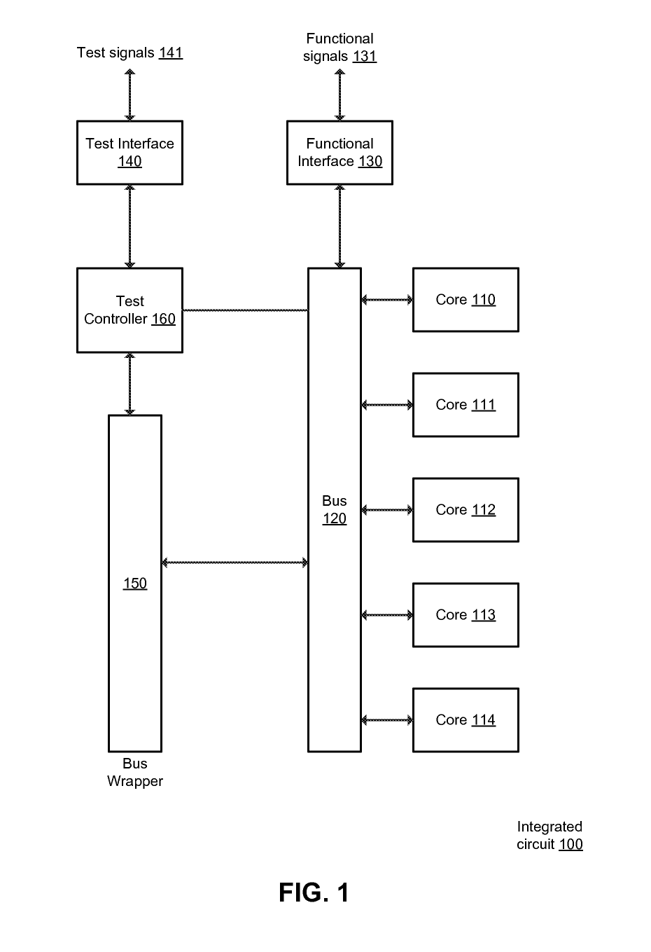

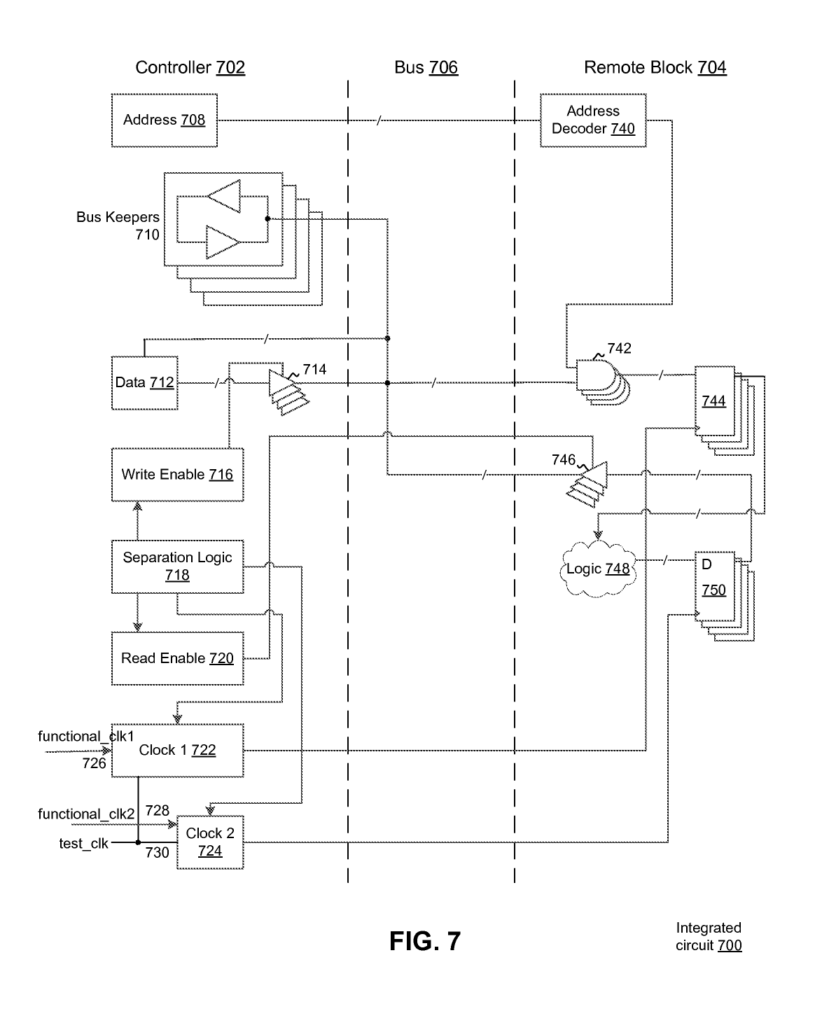

FIG. 1 is a block diagram of an integrated circuit 100. The integrated circuit includes cores 110, 111, 112, 113 and 114, a bus 120, a functional interface 130, a test interface 140, a bus wrapper 150, and a test controller 160. (The functional interface 130, test interface 140, bus wrapper 150, a bus interface, and test controller 160 may generally be implemented together as a master controller 702 as shown in FIG. 7.) The integrated circuit 100 may be an integrated circuit device that includes a die and a package. The integrated circuit 100 may interface with a circuit board and may connect to other integrated circuits.

The cores 110-114 are collections of circuits that are each directed toward a particular function. Examples of the cores 110-114 are a microprocessor core, a Bluetooth™ transceiver core, a digital signal processor core, a power management core, etc. The cores 110-114 may be analog, digital, or mixed analog/digital. The specific cores 110-114 implemented on the integrated circuit 100, and their numbers, may vary depending on the combined functionality desired for the integrated circuit 100. In general, the techniques described below may be used in designs with two or more cores. The cores 110-114 receive inputs from the bus 120, and provide outputs to the bus 120.

The bus 120 connects the cores 110-114 and the other components of the integrated circuit 100. The bus 120 selectively operates in two modes: a functional mode and a test mode. In general, the functional mode corresponds to the integrated circuit 100 operating in its normal, standard manner, and the test mode corresponds to the integrated circuit 100 being tested (e.g., not operating in its normal, standard manner). In functional mode, the inputs to and outputs from the cores 110-114 are functional inputs and outputs. In test mode, the inputs to and outputs from the cores 110-114 are test inputs and outputs. These operational modes are described in more detail below.

The functional interface 130 receives functional inputs from outside of the integrated circuit 100, and provides functional outputs to outside of the integrated circuit 100; these inputs and outputs are collectively referred to as the functional signals 131. When the integrated circuit 100 is operating in the functional mode, the functional interface 130 provides the functional inputs to the cores 110-114 (via the bus 120), and receives the outputs from the cores 110-114 (via the bus 120) as the functional outputs. The functional interface 130 generally includes a number of input and output pins that are directed toward specific functions, such as address input/output, data input/output, clock signals, etc. There may be multiple pins of each particular type, allowing for parallel input or output of data. The functional interface 130 may include components such as registers, buffers, etc.

Alternatively, the functional interface 130 may include one or more of the other components, such as the test interface 140, the bus wrapper 150, and the test controller 160, as an aggregate controller component. The bus wrapper 150 may be considered to be part of the functional interface 130.

The test interface 140 receives test inputs from outside of the integrated circuit 100, and provides test outputs to outside of the integrated circuit 100; these inputs and outputs are collectively referred to as the test signals 141. When the integrated circuit 100 is operating in the test mode, the test interface 140 provides the test inputs to the cores 110-114 (via the test controller 160, the bus wrapper 150 and the bus 120), and receives the outputs from the cores 110-114 (via the bus 120, the bus wrapper 150, and the test controller 160) as the test outputs. The test interface 140 generally includes a number of input and output pins. The test interface 140 may only have a single pin for each particular type, allowing for serial input or output of data. For example, the test interface 140 may be implemented as an IEEE 1149.1 TAP, with five pins TDI, TDO, TCK, TMS and TRST. The test interface 140 may include components such as registers, buffers, etc. In general, the test interface connects to an external test device, such as automated test equipment (ATE). For low pin count devices, the test signals 141 may be a reconfigurable part of the functional signals 131.

The bus wrapper 150 connects between the test interface 140 and the bus 120. Just as the test signals 141 and functional signals 131 may have overlapping signals and reused logic, the connections to the bus 120 also has reused logic. Generally, when area is a concern all of the signals connecting to the bus are reused. This arrangement may be contrasted with other types of wrappers that connect between the test interface and one or more cores without using the functional bus. That is, in many existing systems, each wrapper surrounds a particular core, such that the wrapper communicates with the core without using the functional bus. In contrast, the bus wrapper 150 connects to the cores 110-114 using the bus 120, which is the functional bus. When the integrated circuit 100 is operating in the test mode, the bus wrapper 150 uses the bus 120 to communicate the test signals with the cores 110-114. Further details of the bus wrapper 150 are provided below.

The test controller 160 interfaces between the test interface 140, the bus wrapper 150 and the bus 120. The test controller 160 may be a component of the bus wrapper 150. In general, the controller 702 (see FIG. 7) controls the operational mode of the integrated circuit 100, including, for example, whether the bus 120 is operated in the test mode or in the functional mode. In general, the test controller 160 controls the test mode, including, for example, whether the scan chains are operated in test capture mode or test shift mode. There may be various other modes that the test controller 160 controls. For example, there may be a separate mode for each of the cores 110-114. In the functional mode, the controller 702 controls the bus 120 to receive the functional inputs from the functional interface 130, and to provide the functional outputs to the functional interface 130. In the test mode, the controller 702 provides the test inputs from the test interface 140 to the bus wrapper 150, controls the bus 120 to receive the test inputs from the bus wrapper 150, controls the bus 120 to provide the test outputs to the bus wrapper 150, and provides the test outputs from the bus wrapper 150 to the test interface 140. This allows the test controller 160 to perform testing of the integrated circuit 100 in parallel at the speed of the bus 120.

The operation of the integrated circuit 100 in the test mode is discussed in more detail below, including the operation of the test controller 160, the bus wrapper 150 and the bus 120 in the test mode.

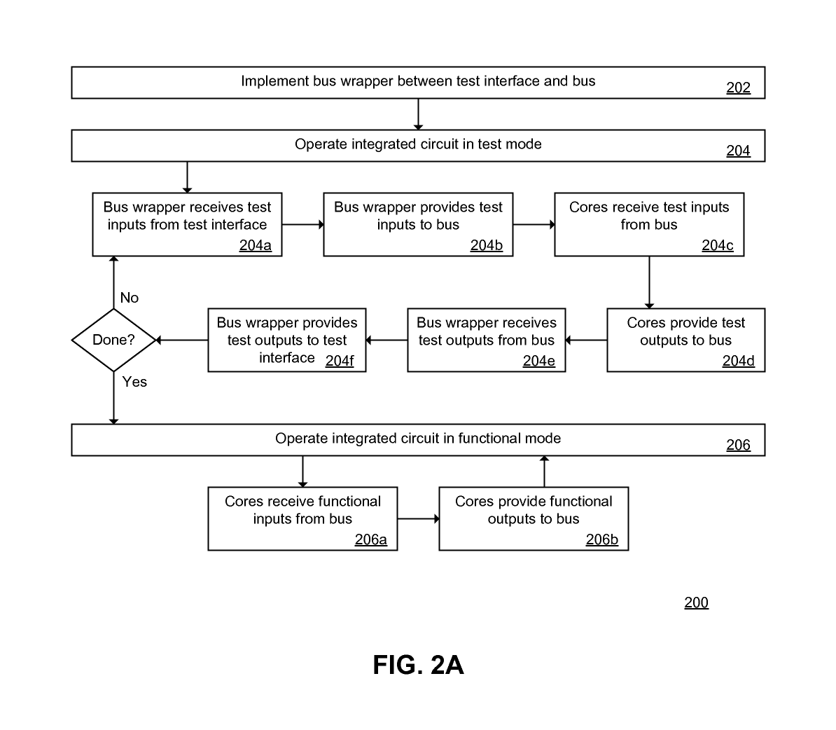

FIG. 2A is a flowchart of a method 200 of testing an integrated circuit that has multiple cores. The method 200 may be performed by the integrated circuit 100 (see FIG. 1), for example.

At 202, a bus wrapper is implemented between a test interface and a bus of the integrated circuit. This placement of the bus wrapper (between the test interface and the bus) may be contrasted with other wrapper placements in which each core has its own wrapper that connects to the core, instead of a shared wrapper that uses the functional bus to connect to the cores. This shared wrapper may also be referred to as a bus wrapper. For example, in FIG. 1 the bus wrapper 150 is between the test interface 140 and the bus 120, and the bus 120 is between the bus wrapper 150 and the cores 110-114. Further note that this placement of the bus wrapper allows the usage of the existing functional bus of the integrated circuit for testing, instead of adding an additional bus (or additional other circuit connections) that is only used for testing.

At 204, the integrated circuit is operated in a test mode. Once 204 occurs, the bus wrapper operates autonomously on the integrated circuit through the bus until either the test control disables the bus wrapper or takes the integrated circuit out of test mode. Note that much of the test mode operation involves the bus, or is performed by the bus. The test mode includes sub-steps 204a, 204b, 204c, 204d, 204e and 204f. A test controller (e.g., the test controller 160 of FIG. 1) may control the operation of the other components of the integrated circuit in the test mode (e.g., to allow the test signals 141, instead of the functional signals 131, to be operated on by the integrated circuit 100).

At 204a, the bus wrapper receives test inputs from the test interface. For example, the bus wrapper 150 (see FIG. 1) receives the test signals 141 from the test interface 140. The test inputs are generally sets of test inputs; each set is tested by the integrated circuit, and the set of outputs is compared to a reference set. So consider at 204a that the bus wrapper receives test inputs from the test interface. As a result, the bus wrapper is loaded with control, address, and data information. The address information includes a portion that selects the core to be tested (the core select address information) and a portion that selects the logic and/or register of the tested core to be addressed (the core address information).

At 204b, the bus wrapper provides the test inputs to the bus. For example, the bus wrapper 150 (see FIG. 1) provides the test signals 141 to the bus 120. As discussed above, consider at 204b that the bus wrapper provides the address and data information of the test inputs to the bus.

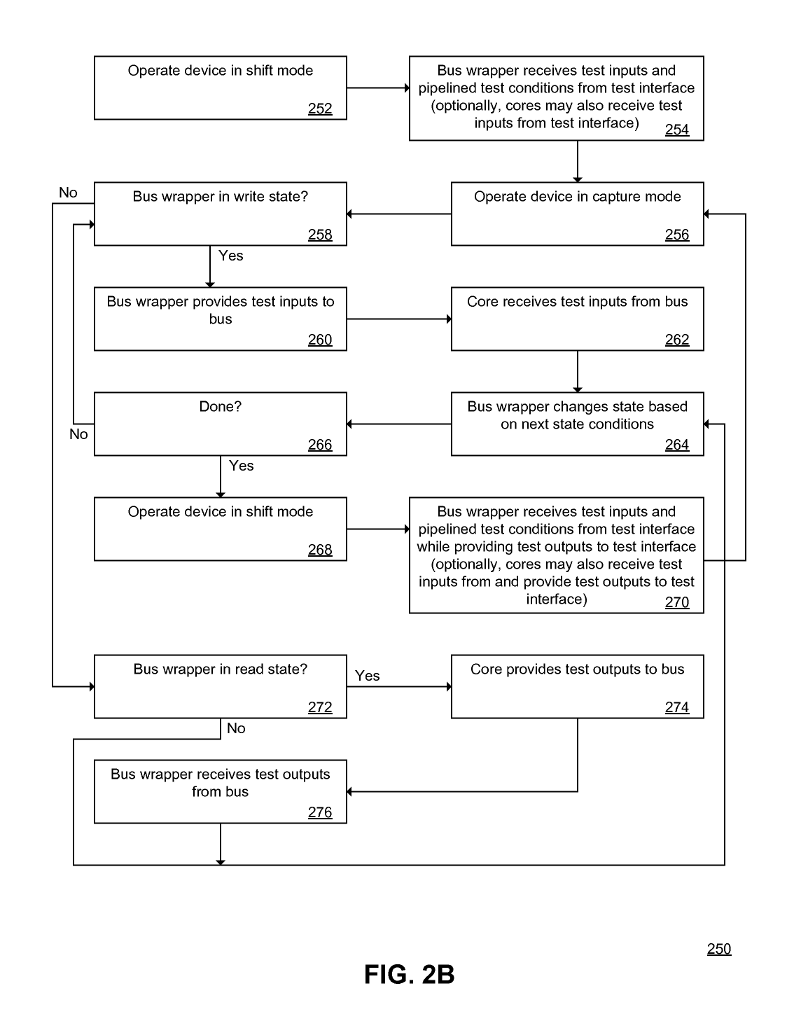

At 204c, the cores receive the test inputs from the bus. In general, a particular set of test inputs is directed to a particular core, according to the core select address information. So consider at 204c that the selected core receives the test inputs. For example, the core 110 (or another of the cores 111-114; see FIG. 1) receives the bus wrapper 150 scan chain parallel outputs (from 312, 314 and 316 in FIG. 3) and the clock output via the bus 120.

Note that the bus provides a connection between the bus wrapper and the cores, so 204b and 204c may be considered together. That is, at 204b-204c, the selected core receives the test inputs from the bus wrapper via the bus. Typically this happens when a clock signal generated by the bus wrapper at 204b arrives at the core triggered at 204c.

At 204d, the cores provide the test outputs to the bus. As discussed above, consider at 204d that the selected core provides test outputs that correspond to the selected core operating on the test inputs. For example, the core 110 (or another of the cores 111-114; see FIG. 1) provides, to the bus 120, the test outputs that correspond to the core 110 operating on the test inputs. The core may operate on the test inputs at any time between 204c and 204d, or this may occur as a substep of 204c or 204d.

At 204e, the bus wrapper receives the test outputs (also referred to as the test results) from the bus. As discussed above, consider at 204e that the bus wrapper receives the test outputs that correspond to the selected core operating on the test inputs. For example, the bus wrapper 150 (see FIG. 1) receives from the core 110 (or another of the cores 111-114), via the bus 120, the test outputs that corresponds to the core 110 operating on the test inputs.

Note that the bus provides a connection between the bus wrapper and the cores, so 204d and 204e may be considered together. That is, at 204d-204e, the bus wrapper receives the test outputs from the selected core via the bus.

At 204f, the bus wrapper provides the test outputs to the test interface. For example, the bus wrapper 150 (see FIG. 1) provides the test outputs to the test interface 140 (e.g., via the test controller 160, or the controller 702 of FIG. 7).

The test mode operation of 204 (e.g., 204a-204f) may be repeated as desired for sets of test inputs, resulting in sets of test outputs. For example, multiple sets of test inputs may be sent to each core, and the multiple sets of test outputs may be compared to the expected reference values. Note that 204a and 204f may occur at the same time (simultaneously, contemporaneously, etc.), since as test inputs are shifted in at 204a, test outputs may be shifted out at 204f. Once the testing has been completed, the method 200 proceeds to 206.

At 206, the integrated circuit is operated in a functional mode. Note that the functional mode involves the bus since the bus is the functional bus for communicating functional inputs and outputs to the functional cores. The functional mode includes sub-steps 206a and 206b. A test controller (e.g., the test controller 160 of FIG. 1, the controller 702 of FIG. 7, etc.) may control the operation of the other components of the integrated circuit in the functional mode (e.g., to allow the functional signals 131, instead of the test signals 141, to be operated on by the integrated circuit 100).

At 206a, the cores receive the functional inputs from the bus. Generally, the functional inputs are a set of functional inputs that includes address and data information. The address information includes a portion that selects the core to be operated (the core select address information) and a portion that selects the register of the selected core to be addressed (the core address information). The selected core then operates on the data. For example, the core 110 (or one of the cores 111-114 of FIG. 1) receives the functional signals 131 (the functional inputs) from the bus 120 via the functional interface 130.

At 206b, the cores provide the functional outputs to the bus. The functional outputs correspond to the selected core operating on the set of functional inputs (e.g., on the data of the data portion, according to the address in the address portion). For example, the core 110 (or one of the cores 111-114 of FIG. 1) provides the functional signals 131 (the functional outputs) to the functional interface 130 via the bus 120.

The functional mode operation of 206 may be repeated as desired for additional sets of functional inputs. This operation corresponds to the integrated circuit operating according to its normal, standard, intended-use mode of operation. Note that if desired, the integrated circuit may be controlled to re-enter the test mode operation of 204.

Note that the functional mode operation of 206 is often performed quite removed in time and place from the test mode operation of 204. For example, the test mode operation of 204 may be performed before the integrated circuit is provided to a downstream customer or consumer, when the integrated circuit is connected to test equipment. The downstream customer or consumer then operates the integrated circuit in the functional mode of 206 by powering on the integrated circuit and operating it according to its standard, normal, intended use (e.g., when the integrated circuit is unconnected to test equipment).

Alternatively, the functional mode and test mode may be performed alternately or selectively, for example by the downstream customer. The downstream customer may operate the device in functional mode, and then may connect the device to test equipment and operate the device in test mode. Then the downstream customer may return the device to functional mode operation.

Note that various embodiments of the integrated circuit 100 (see FIG. 1) need not perform all the steps of the method 200 in order to take advantage of the benefits of the bus wrapper 150 (see FIG. 1). According to an example embodiment, in the test mode, the bus wrapper receives the test inputs from the test interface (204a) and provides the test inputs to the bus (204b), and the cores receive the plurality of test inputs from the bus (204c). According to another example embodiment, in the test mode, the cores generate the test outputs from the test inputs and provide the plurality of test outputs to the bus (204d), and the bus wrapper receives the test outputs from the bus (204e). According to another example embodiment, in the test mode, the bus wrapper receives the test inputs from the test interface (204a) and provides the test inputs to the bus (204b), the cores receive the test inputs from the bus (204c), generate the test outputs from the test inputs, and provide the test outputs to the bus (204d), and the bus wrapper receives the test outputs from the bus (204e).

According to another example embodiment, in the test mode, the bus wrapper receives the test inputs from the test interface (204a) and provides the test inputs to the bus (204b), the cores receive the test inputs from the bus (204c), generate the test outputs from the test inputs, and provide the test outputs to the bus (204d), and the cores receive the test outputs from the bus and generate a second set of test outputs from the test outputs. This allows the cores to generate and operate on intermediate outputs. For example, the outputs from one core may be used as the inputs of another core.

According to another example embodiment, in the functional mode, the cores receive the functional inputs from the bus (206a), generate the functional outputs, and provide the functional outputs to the bus (206b). The integrated circuit 100 may then use the bus to route these functional outputs to other cores (e.g., these functional outputs are intermediate results), to the functional interface, etc. as desired.

FIG. 2B is a flowchart of a method 250 of testing an integrated circuit that has at least one remote core. The method 250 provides more details of the test mode operation (see 204 in FIG. 2A). Specifically, the method 250 describes that the test mode (see 204 in FIG. 2A) includes shift mode and capture mode (also referred to as test shift mode and test capture mode), as further detailed below. The method 250 may be performed by the integrated circuit 100 (see FIG. 1), for example, as controlled by the test controller 160. Throughout the method 250, the test controller 160 has selected to be in a state in which the bus wrapper 150 is acting autonomously. FIG. 2B provides more detail for the steps shown in 204 (see FIG. 2A). As mentioned above, the operations of the method 250 may be performed in other orders, operations may be performed concurrently, etc.

At 252, the test controller controls the device such that selected cores operate in shift mode. Shift mode may be contrasted with capture mode (see 256 below). In general, shift mode refers to the bus wrapper receiving test inputs (see 254 and 270 below) or receiving test inputs and providing test outputs (see 270 below). Shifting is typically done serially, with the registers hooked together into n chains, with n inputs and n outputs. For example, the test controller 160 (see FIG. 1) controls the operation of the integrated circuit 100 in shift mode. The method proceeds to 254, a submode of the shift mode 252.

At 254, the bus wrapper receives the test inputs and pipelined test conditions, shifted in, from the test interface. For example, the test inputs are “shifted into” the bus wrapper. (The pipeline and the pipelined test conditions are described in subsequent sections.) For example, the bus wrapper 150 (see FIG. 1) receives the test signals 141 from the test interface 140. The test signals 141 include the test inputs and the pipelined test conditions. The method proceeds to 256.

At 256, the device operates in capture mode, leaving the shift mode. Capture mode may be contrasted with shift mode (see 252 above or 268 below). In general, capture mode refers to the bus wrapper providing the test inputs to the bus (see 260 below) or receiving the test outputs from the bus (see 276 below). For example, the bus wrapper 150 (see FIG. 3) controls the operation of the bus 120 in capture mode. The method proceeds to 258, a submode of the capture mode 256.

At 258, if the bus wrapper is in the write state, the method proceeds to 260, a submode of the capture mode 256. If the bus wrapper is not in the write state, the method proceeds to 272. For example, the bus wrapper 150 (see FIG. 3) controls the operation of the bus 120 in the write state by sending a write enable signal to the cores 110-114.

At 260, the bus remains in the write state, and the bus wrapper provides the test inputs to the bus. For example, the bus wrapper 150 (see FIG. 1) provides the test inputs to the bus 120. The method proceeds to 262.

At 262, the selected one or more cores receive the test inputs from the bus. (The selected one or more cores may operate on the test inputs and generate the test outputs, in accordance with their functional operation, prior to 274 below.) For example, one or more of the cores 110-114 (see FIG. 1) receive the test inputs from the bus 120. The method proceeds to 264.

At 264, the bus wrapper changes state based on the next state conditions. For example, if the bus wrapper is in the write state (see 258 to 260 to 262) and the next state is the read state, the bus wrapper changes to the read state. If the bus wrapper is in the read state (see 272 to 274 to 276) and the next state is the write state, the bus wrapper changes to the write state. For example, the bus wrapper 150 (see FIG. 3) controls the enable portion 306 to change state based on the next state conditions. The method proceeds to 266.

At 266, if the device is finished with capture mode operation, the method proceeds to 268. If the device is not finished with capture mode operation, the method returns to 258. For example, the test controller 160 (see FIG. 1) controls whether or not the integrated circuit 100 is finished with capture mode operation.

At 268, the device operates in shift mode. Shift mode may be contrasted with capture mode (see 256 above). For example, the test controller 160 (see FIG. 1) controls the integrated circuit 100 to operate in shift mode. The method proceeds to 270.

At 270, the bus wrapper receives the test inputs and pipelined test conditions from the test interface while providing the test outputs to the test interface. For example, the test inputs are “shifted into” the bus wrapper, and the test outputs are “shifted out of” the bus wrapper. The receiving and the providing may occur simultaneously or contemporaneously. Optionally, one or more of the cores may also receive the test inputs from the test interface, and may also provide the test outputs to the test interface. For example, the bus wrapper 150 (see FIG. 1) receives the test signals 141 from the test interface 140. The test signals 141 include the test inputs and the pipelined test conditions. The bus wrapper 150 provides the test outputs to the test interface 140. Optionally, one or more of the cores 110-114 may also receive the test signals 141 from the test interface 140, and may provide the test outputs to the test interface 140. The method returns to 256.

At 272, if the bus wrapper is in the read state, the method proceeds to 274. If the bus wrapper is not in the read state, the method returns to 256. For example, the bus wrapper 150 (see FIG. 3) checks the read enable 720 (see FIG. 7, for example with the controller 702 implementing the bus wrapper) to determine its state.

At 274, the selected core provides the test outputs to the bus. (The core has generated these test outputs in the time after receiving the test inputs at 262 above.) For example, the core 110 (see FIG. 1) provides the test outputs to the bus 120. The method proceeds to 276.

At 276, the bus wrapper receives the test outputs from the bus. For example, the bus wrapper 150 (see FIG. 1) receives the test outputs from the bus 120. The method returns to 264.

The serial, in other words shift, and parallel, in other words capture, operation of the test mode can be seen in FIG. 2B. As is typical for ATPG, the operations that occur during shift mode are performed serially for each scan chain, and the operations performed that occur during capture mode are performed in parallel on the active parts of the integrated circuit. The test interface 140 (see FIG. 1) provides data serially to the bus wrapper 150 during shift mode. The device then switches to capture mode and the data is provided in parallel to the bus by the bus wrapper 150. Whether the integrated circuit 100 is in test mode, which parts of the integrated circuit 100 are active, whether the bus wrapper 150 is active, and whether the active circuits (e.g., the cores 110-114) are in shift mode or capture mode are all elements that are controlled by the test controller 160. During the capture mode, the bus wrapper 150 acts on the bus 120 autonomously. The test controller 160 is typically a TAP controller. It controls the data flow from the test interface, which may or may not be a TAP and which may or may not be part of the functional interface. The inputs from the test interface are provided to the bus wrapper 150 serially. Similarly when the test is complete, the test controller switches to shift mode and shifts out the data serially from the bus wrapper 150 to the test interface 140.

FIG. 3 is a block diagram showing additional details of an integrated circuit 300 (cf. the integrated circuit 100 of FIG. 1). The integrated circuit 300 is similar to the integrated circuit 100, but for brevity omits some of the components, while providing more detail for other components. Additionally for brevity, the operation of the integrated circuit 300 is discussed with reference to the test mode, but note that it also operates in the functional mode; for example, in the functional mode, the bus 120 communicates functional inputs and outputs with the core 110 (e.g., from and to the functional interface 130). The integrated circuit may implement the method 200 (see FIG. 2A), the method 250 (see FIG. 2B), or portions thereof.

The integrated circuit 300 includes the bus wrapper 150, the bus 120, and the core 110 (see FIG. 1). The integrated circuit 300 also includes other cores (not shown).

The bus 120 includes address lines (for brevity only 4 are shown) and data lines (for brevity only 4 are shown). The address lines communicate address information to the cores, and the data lines communicate data with the cores. The bus 120 may include additional, or fewer, address lines and data lines than the four shown. The address lines may include one or more core select lines. The core select lines select one or more of the cores to receive the address information and the input data from the bus 120, and to select one core to provide the output data to the bus 120. The core select lines are controlled, as part of the address, by the test controller 160 (see FIG. 1). There may be various other signals that are active and may be required to be in a particular state in order for the bus wrapper 150 to work with a particular core.

The bus wrapper 150 receives test inputs 320 and outputs test outputs 321. The test inputs 320 and outputs 321 correspond to the test signals 141 (see FIG. 1). The test inputs 320 provide the input(s) to one (or more) scan chain(s), and the test outputs 321 receive the output(s) from one (or more) scan chain(s). The bus wrapper 150 is part of one (or more) scan chains and, thus, receives the test inputs 320 and provide the test outputs 321 by way of the test controller 160 or the test interface 140 (see FIG. 1).

The bus wrapper 150 includes an address portion 302, a data out portion 304, an enable portion 306, and a data in portion 308. The address portion 302 stores the address information from the test inputs 320. The data out portion 304 stores the test data inputs from the test inputs 320. The data in portion 308 stores the test data outputs resulting from the core 110 operating on the test data inputs, received via the data lines of the bus 120. The data in and data out storage elements 304 and 308 can be combined into a single data storage element, where the data stored is the most recent of either data in or data out. The enable portion 306 stores one or more enable bits (also referred to as control bits) that are used to control aspects of the bus wrapper 150 and other circuits of the integrated circuit 100. The enable portion 306 controls the data circuits 314 and 348.

The address circuits 312 provide the address information from the address portion 302 to the address lines of the bus 120. The data circuits 314 provide the test data inputs from the data out portion 304 to the data lines of the bus 120. The enable circuit 316 disables the data circuits 348 (also referred to as output drivers 348) when the data circuits 314 are enabled, and enables the data circuits 348 when the data circuits 314 are disabled. The data circuits 318 provide the test data outputs from the data lines of the bus 120 to the data in portion 308.

The core 110 includes all its normal functional circuitry, which may include a multiplexer 330, an address decoder portion 332, a data in portion 334, a data out portion 338, and core circuitry 340. The multiplexer 330 provides the test data inputs from the data lines of the bus 120 to the data in portion 334, as controlled by the address decoder portion 332. The multiplexer 330 may also be used to route data from other locations including, for example, simply routing the data in value from previous cycles so that it is retained for the next cycle. The address decoder portion 332 decodes and optionally stores the address information from the address lines of the bus 120. If the decoded address matches the address designated for core 110, the data in portion 334 receives and optionally stores the test data inputs, from the data lines of the bus 120 via the multiplexer 330. The data out portion 338 provides and optionally stores the test data outputs generated by the core 110 in response to the test data inputs. The core circuitry 340 operates on the address information, the test data inputs, and functional signal inputs to generate the test data outputs. The data circuits 348 control the access to the data bus and all the test data outputs from the data out portion 338 to be provided to the data lines of the bus 120.

The bus wrapper 150 may be configured as scan registers. Scan registers may also exist elsewhere throughout the integrated circuit and may or may not be active with the bus wrapper 150. The bus wrapper 150 may include self-feeding flip-flops that are loaded through the scan path. For example, the test controller 160 (see FIG. 1) may receive the test inputs 320 from the test interface 140 and provide them to the bus wrapper 150. The bus wrapper 150 drives the address, data and enable bits onto the bus 120. Test results are observable in the data bits output from the data out portion 338 and received by the data in portion 308. In some cases remote cores may have scan chains in them. In these cases, the test results may be observed via the remote core scan bits, which form the scan chains. In other cases, remote cores may not have any scan chains in them or may only have limited scan chains. In these cases, the test results can be observed either by reading them from the data out of the core 110 to the data in of the bus wrapper 150 and scanning them out, or by observing them directly at the functional output signals of the core.

A novel technique for handling multiple asynchronous clocks for the integrated circuit 300 (or the integrated circuit 100 of FIG. 1) is shown in FIG. 7.

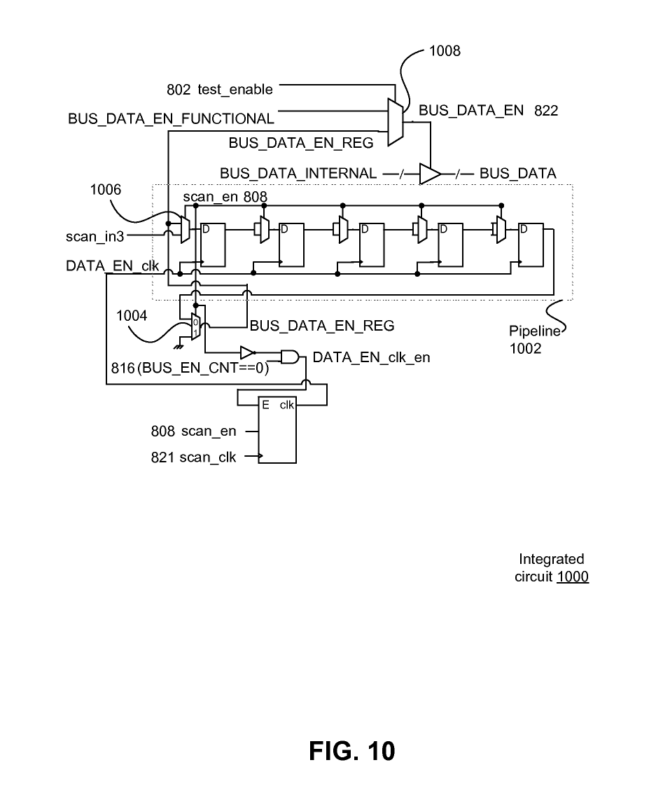

The operation of the integrated circuit 300 in test mode is generally as follows. First, the write enable operation is performed. In the write enable operation, the bus wrapper 150 drives the address, data and enable bits, and clock signals to the core under test (e.g., the core 110), via the bus 120. More specifically, the address portion 302 drives the address bits to the address decoder portion 332 via the address lines of the bus 120; the data out portion 304 drives the data bits to the data in portion 334 via the data lines of the bus 120; the enable portion 306 drives an enable signal to enable the data circuits 314 (and to disable the data circuits 348). The core circuitry 340 then operates on these test inputs and stores the test outputs in the data out portion 338. FIG. 10 shows an example implementation of the write enable operation.

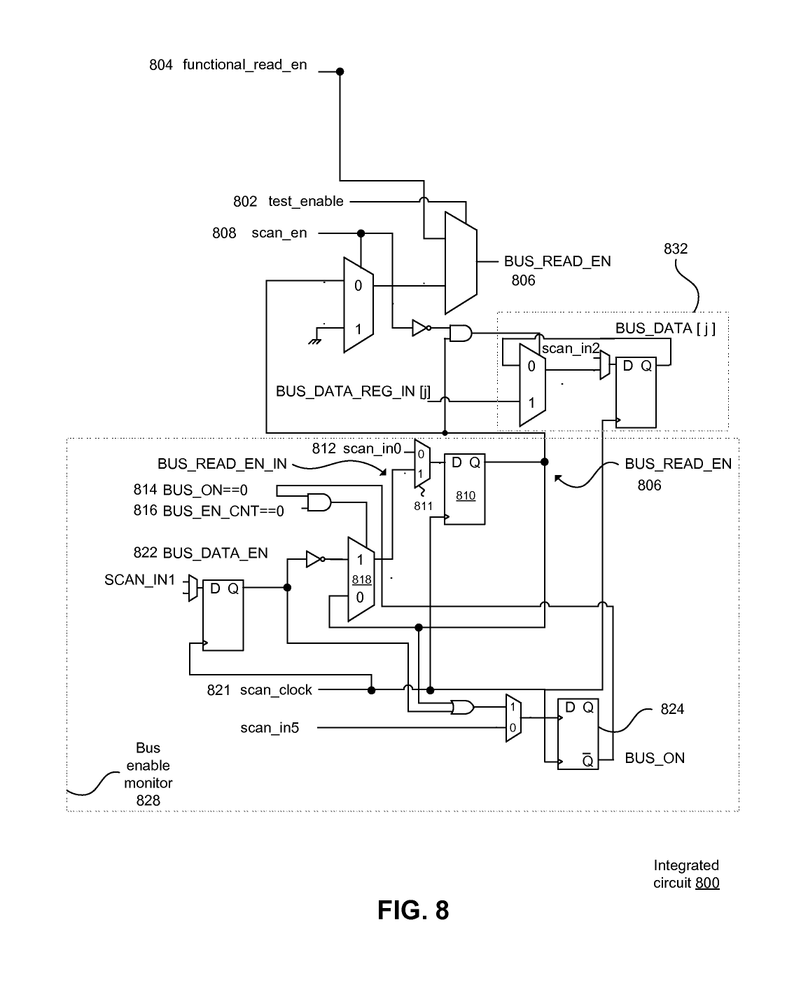

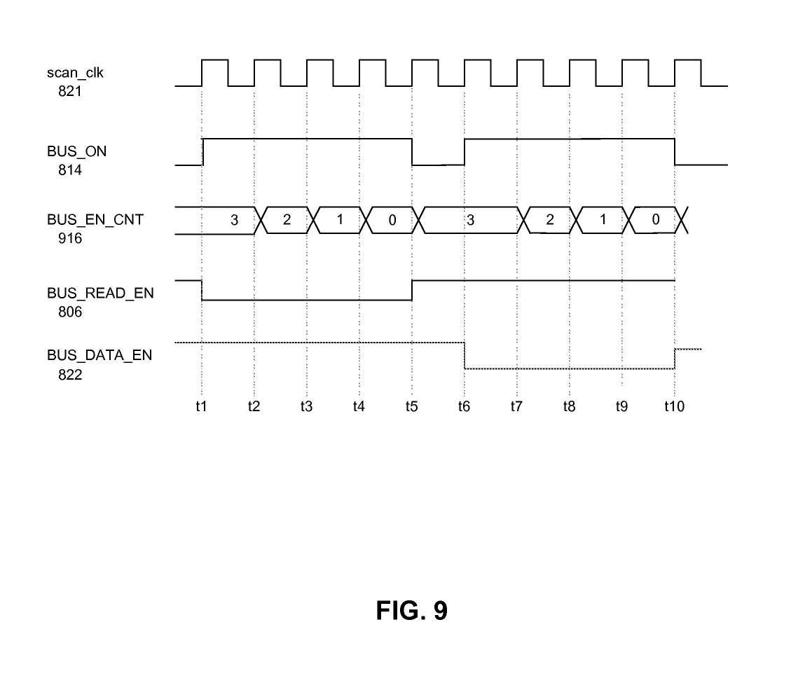

Next, the read enable operation is performed. In the read enable operation, the bus 120 is disabled. The test controller 160 (see FIG. 1) controls disabling the bus 120 by forcing the bus 120 to be disabled during shift mode. The bus wrapper 150 is loaded from the scan input. For example, the test controller 160 (see FIG. 1) may load the test inputs 320 into the bus wrapper 150 from the test interface 140. The test controller 160 (see FIG. 1) may also load other scan cells either directly or from external test equipment through the test interface 140. These other scan cells form other scan chains, which can be located anywhere in the device and may or may not impact the results of the bus test. The test controller 160 (see FIG. 1) may implement special programmable timing structures to control the enable operations. FIG. 8 shows an example of how the read enable operation can be implemented. FIG. 9 shows the timing diagram for the operations shown in FIG. 8.

Next, the enable portion 306 enables the data circuits 348 (and disables the data circuits 314), and the bus wrapper 150 receives the test outputs. More specifically, data from the remote core data out portion 338 is driven by the output drivers 348 to the bus wrapper data in portion 308 via the data lines of the bus 120. The sequence of the enabling and disabling of the bus drivers is programmable and can occur in any order and for any number of times. This is controlled by the pipeline 1002 shown in FIG. 10.

Finally, the bus 120 is disabled, and the test results are scanned out as the test outputs 321. These results can come from scan registers in either the bus wrapper 150 or any of the cores 110 through 114. The test controller 160 (see FIG. 1) may control disabling the bus 120. Or, this may be done from the bus wrapper 150 using a circuit similar to the one shown in FIG. 10, the one shown in FIG. 8, or a combination of the two. The test controller 160 may control providing the test outputs 321 to the test interface 140.

The structure of the integrated circuit 300 or the integrated circuit 100 (see FIG. 1), where the bus 120 acts as an interface between the bus wrapper 150 and the cores 110-114, provides a number of advantages over many existing test structures. (As mentioned above, many existing test structures put a dedicated wrapper around each core, and do not use the functional bus for communicating test signals between a core and its corresponding wrapper.) Having a wrapper on the bus in this way is an advantage because it takes up less silicon area than having a wrapper at each of the cores would take. Additionally, having a wrapper remote to the core is an advantage if the core has already been designed, logically or physically, because while design changes to the core are may be beneficial, they are optional. When the test controller 160 puts the circuit 300 (or 100) in test mode and a core (e.g., the core 110) in non-test mode, or in the functional mode, or in another mode in which it is powered on, one advantage is that core setup operations may be performed. Many existing test structures cannot perform core setup operations because they are not accessible in test mode or the interface through which they are accessible is unacceptably slow. Another advantage is that data may be downloaded directly to the cores 110 through 114 via the bus 120. Many existing test structures cannot download data to the cores because they are not accessible in test mode or the interface through which they are accessible is unacceptably slow. As a result, the test signals may be communicated at higher speeds using the increased bandwidth of the bus 120. Many existing test structures are limited to the serial data rate of their test interface and do not take advantage of communicating their test signals in parallel to the functional bus. For example, the bus wrapper 150 can be configured such that it communicates through many serial interfaces. Typically, in test mode the TAP controller is not limited to a single serial input and output for loading data into and retrieving data from cores 110 through 114 of the device. These can be broken up into multiple serial chains depending on the number of inputs and outputs available for testing. Further, chain data can be compressed and decompressed or serialized and deserialized using a variety of techniques that allow a single or few pins to send data to multiple scan chains and allows multiple scan chains to deliver data to a single or few pins. For example, in functional mode functional signals 131 may communicate to the bus 120 at a fixed rate. However, for testing purposes the test interface 140 uses test signals 141, which may include functional signals 131, plus additional signals that may be available in test mode, but not functional mode.

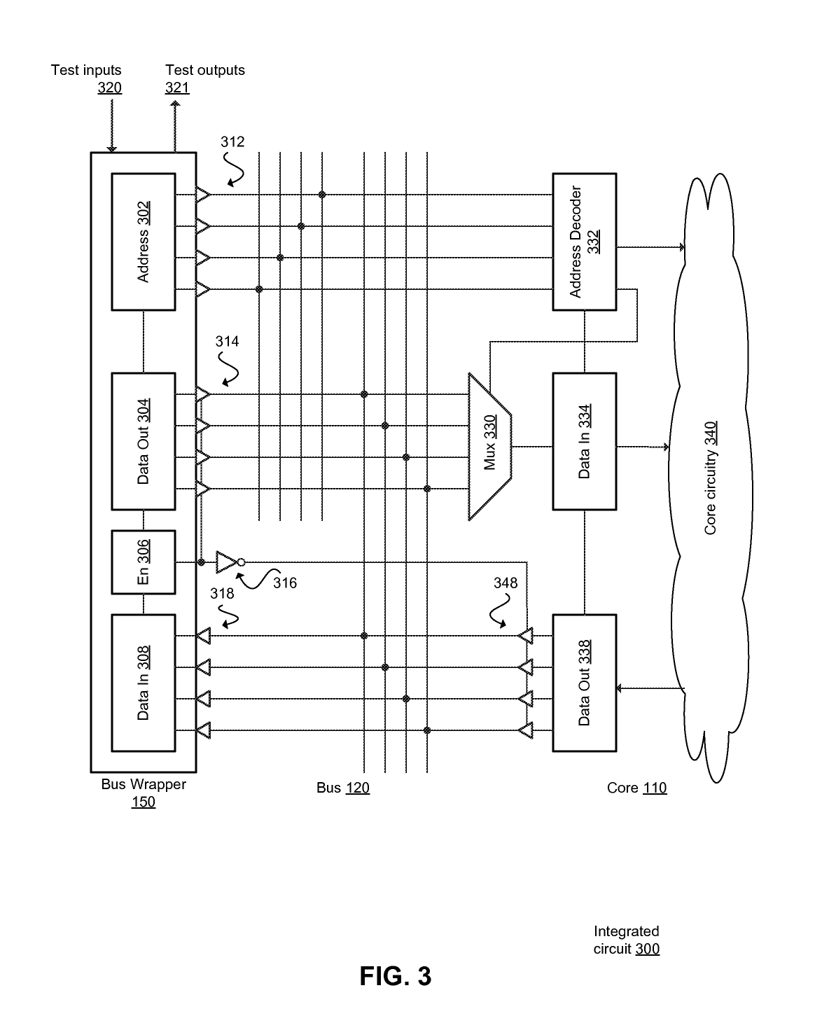

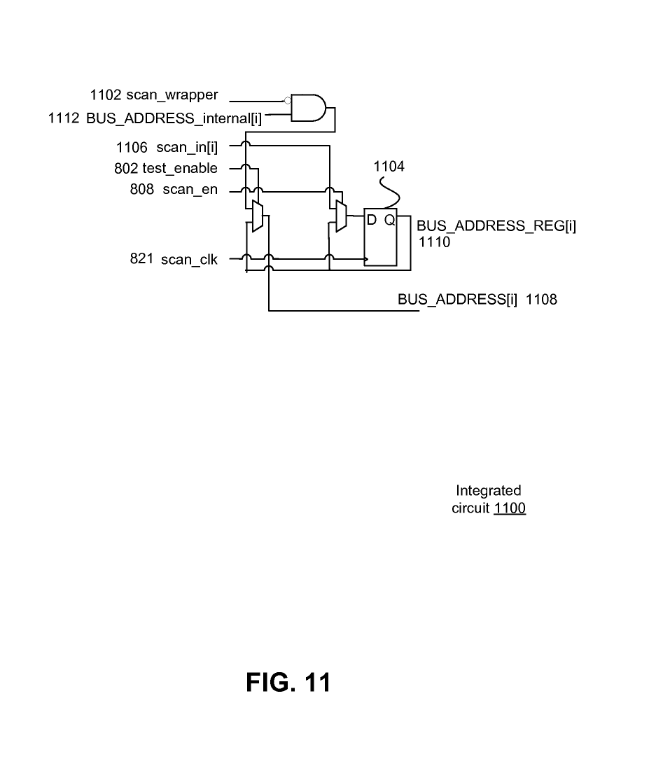

FIG. 4 is a block diagram of a recirculating cell 400. (Additional details of the cell 400 are provided in FIG. 11.) The cell 400 includes a multiplexer 402, a flip-flop (or register) 404, and a multiplexer 406. The multiplexer 402 receives the scan input Si and the output of the flip-flop 404. The scan input Si may be one of the bits of an input scan chain, for example as provided in the test signals 141 (see FIG. 1). The test controller 160 (see FIG. 1) controls the multiplexer 402 (via a scan enable line 808, shown in FIG. 11) to select the scan input Si (see, e.g., scan_in[i] 1106 in FIG. 11) for input into the flip-flop 404 at the appropriate time. Otherwise, the multiplexer 402 feeds back the output (see also 1110 in FIG. 11) of the flip-flop 404 (or 1104 in FIG. 11) as the input to the flip-flop 404 (or 1104 in FIG. 11). The flip-flop 404 stores the scan input Si. The multiplexer 406 receives the output (see also 1110 in FIG. 11) from the flip-flop 404 (or 1104 in FIG. 11, the stored scan input Si) and the functional input 412 (or 1112 in FIG. 11, e.g., derived from one or a combination of the functional signals 131 of FIG. 1). The test enable signal 414 (or 802 in FIG. 11, e.g., from the test controller 160 of FIG. 1) selects either the functional input 412 (when operating in the functional mode) or the scan input Si (when operating in the test mode), and the multiplexer 406 provides the selected input to the bus 120.

When the cell 400 implements the address portion 302 (see FIG. 3), it connects to the test controller 160 of FIG. 1 (e.g., to receive the scan input Si as one of the test signals 141, and to receive the test enable signal 414), to the bus 120 (see FIG. 1 and FIG. 3), and to the functional interface 130 of FIG. 1 (for example, to receive data derived from the functional input 412 as one of the functional signals 131).

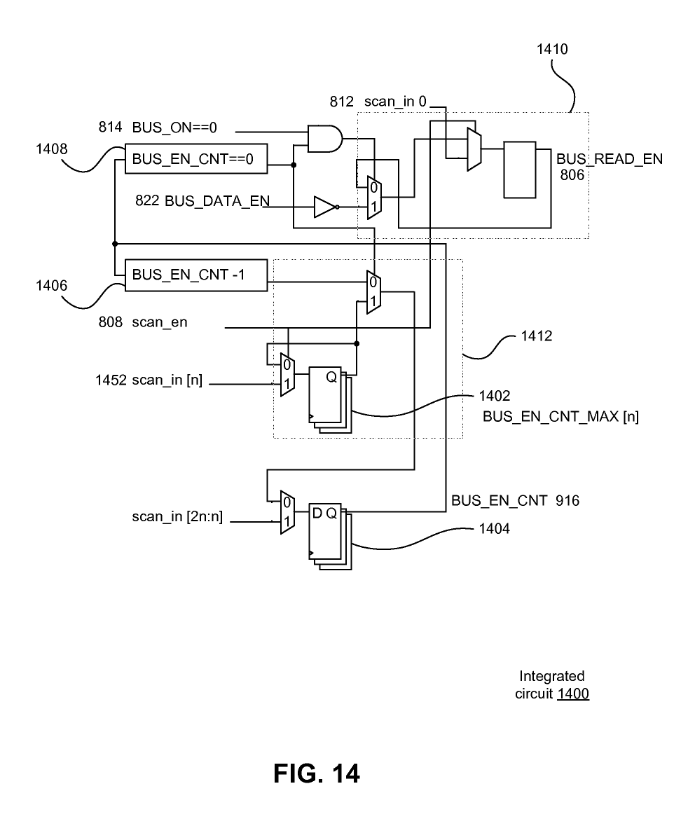

The cell 400 may be thought of as a recirculating cell because it could be used anywhere or anytime that a fixed state is required. (For example, FIG. 14 shows a recirculating cell that, because of the counter, switches on a time dependent basis.) The scan input Si is hooked to the output of a preceding scan chain, directly to an input, to the output of a decompressor, or to the output of a deserializer. The output Q is hooked to the input of the following scan chain, directly to an output, to the input of a compressor, to the input of deserializer, or it need not be connected to anything. For example, if there are 4 address bits, one may implement the bus wrapper with 4 address cells connecting the first address cell's scan input Si to the output of a preceding scan chain and its output Q to the scan input Si of the second address cell, and so on. The output Q of the fourth address cell could be connected to the device output. This is how scan chains typically work, and all of the bus wrapper scan cells would be connected together in this way.

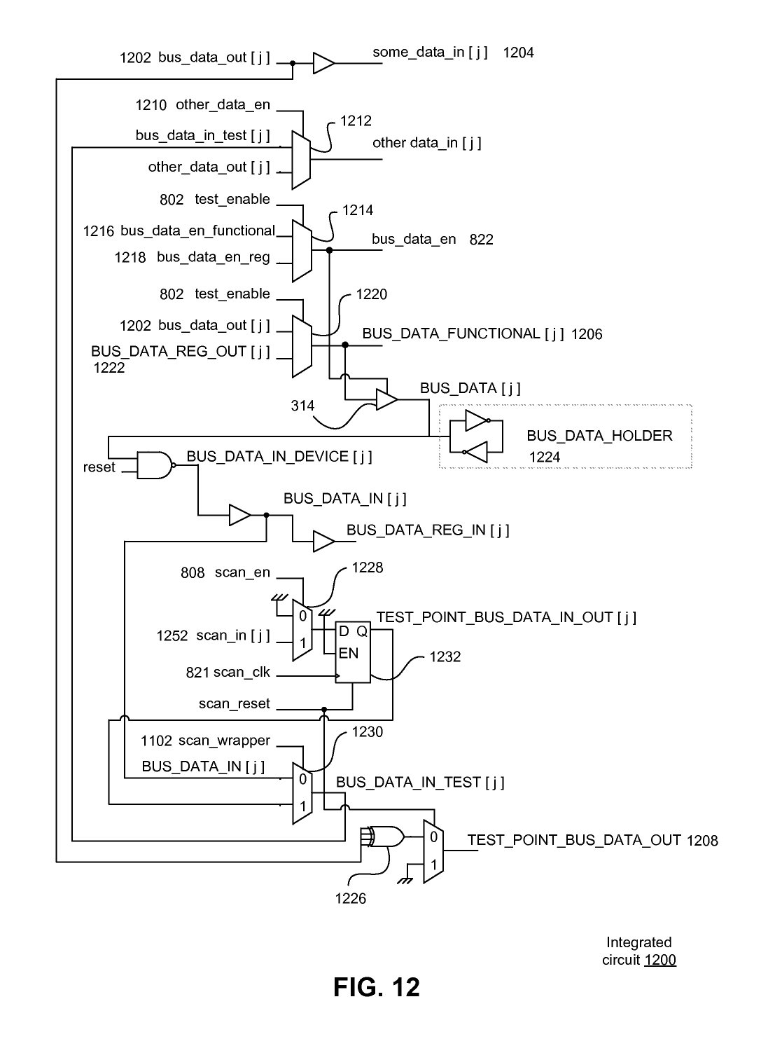

The controller core is made up of the functional interface 130, the test interface 140, the bus wrapper 150, the test controller 160, and any other controlling logic not included in the remote cores 110-114 or bus 120 (see FIG. 1). The data out portion 304, the enable portion 306, and the data in portion 308 (see FIG. 3) may include cells similar to the cell 400 in that they may be recirculating. For example, the cell for bus data is shown in FIG. 12.

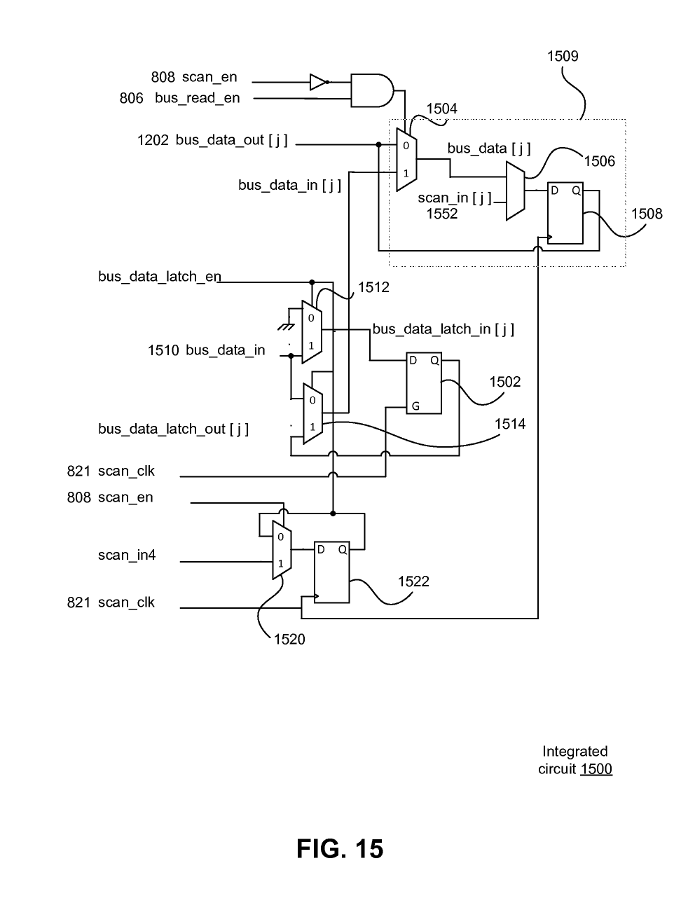

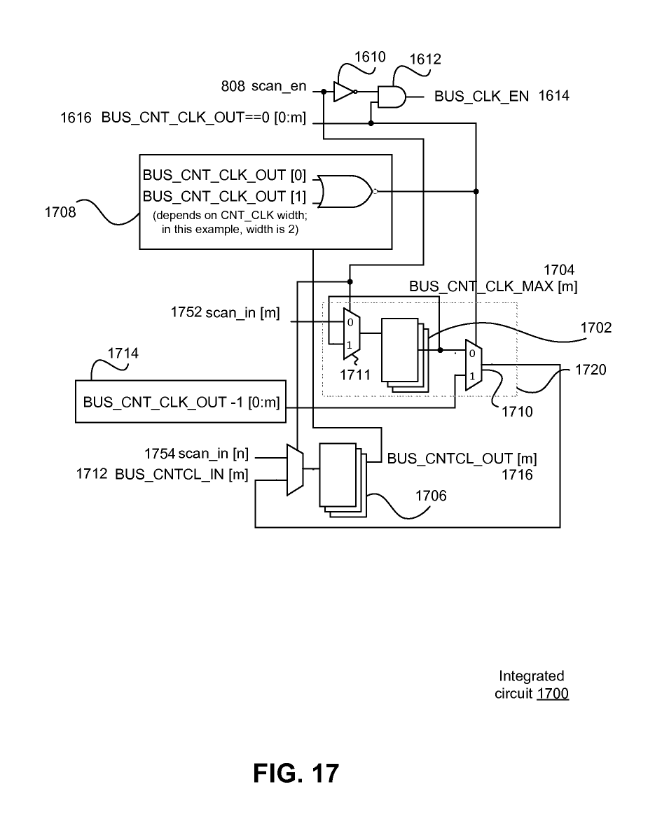

The recirculating cell 400 may be implemented in one or more of the circuits shown in other of the figures. For example, the address portion 302 (see FIG. 3) with four outputs may be implemented using four recirculating cells 400. FIG. 11 shows an example of how the recirculating cell 400 may be implemented in the address portion 302. FIG. 8 includes a recirculating cell 832. Also in FIG. 8, the multiplexers 811 and 818, and the flip-flop 810, form a recirculating cell for the bus read enable signal BUS_READ_EN 806. In FIG. 14, the recirculating cell 1410 for the bus read enable signal BUS_READ_EN 806 includes two multiplexers and a flip-flop. Also in FIG. 14, the flip-flops 1402 (also referred to as the max value registers or the start value registers) and the associated multiplexers form a recirculating cell 1412 for the bus enable counters. In FIG. 15, the multiplexers 1504 and 1506, and the flip-flop (also referred to as a register) 1508, form a recirculating cell. Also in FIG. 15, the multiplexers 1512 and 1520, and the flip-flop 1522, form a recirculating cell for the bus data latch enable signal bus_data_latch_en. In FIG. 17, the recirculating cell 1720 for the bus count clock start value BUS_CNT_CLK_MAX[m] 1704 includes the flip-flops 1702 and the associated multiplexers 1710 and 1711.

One or more (or all) of the recirculating cells discussed in the previous paragraph, or in other figures, may be replaced with an arbitrary length pipeline (such as the pipeline 1002 of FIG. 10).

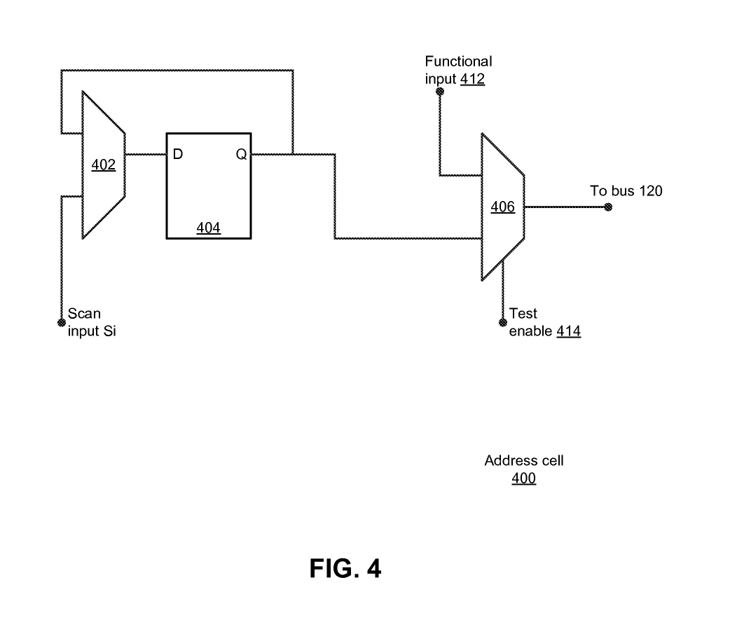

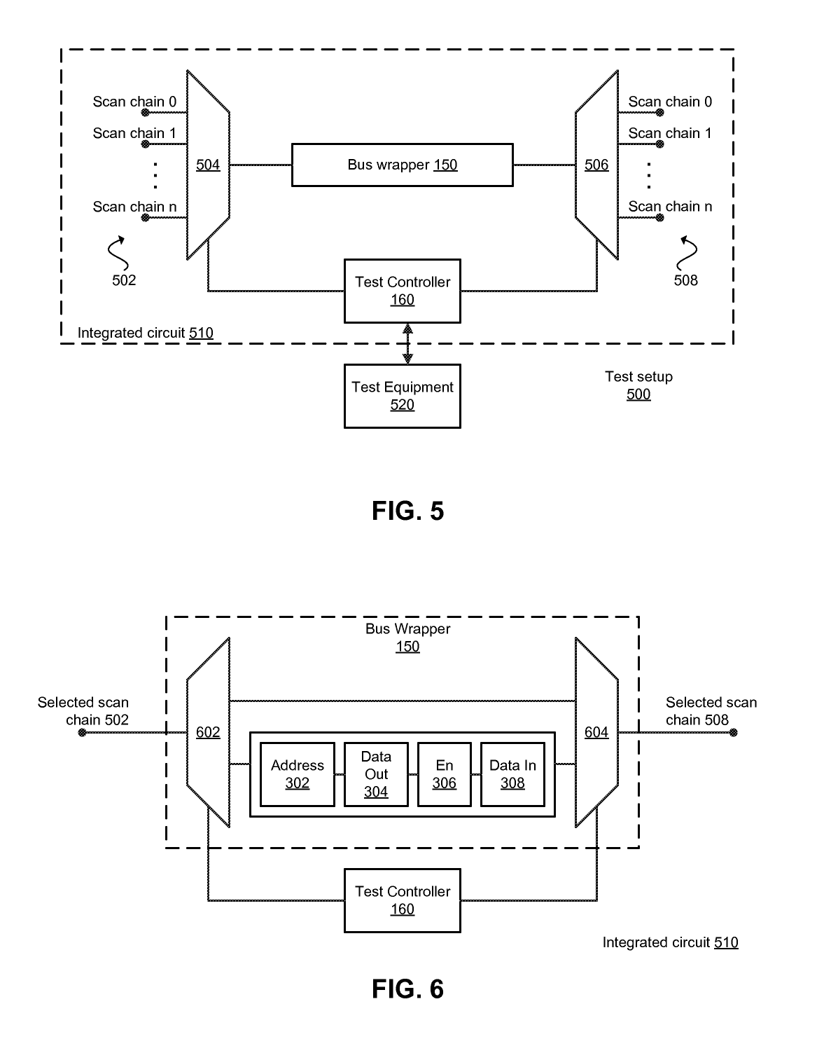

FIG. 5 is a block diagram showing how the bus wrapper 150 (see FIG. 3) may be integrated with the other scan chains in an integrated circuit 510. Each of the scan chains shown may correspond to the scan chain in one of the remote cores 110 to 114, to chains elsewhere within the controller, or to chains elsewhere in the integrated circuit 510. FIG. 6 is a block diagram showing how the test controller 160 (see FIG. 3) can bypass the bus wrapper 150, which is made up of 302, 304, 306, 308, 602, and 604, but not 502 and 508. Selected chain 502 in FIG. 6 may correspond to any of the 0 to n scan chains 502 in FIG. 5. Selected chain 508 in FIG. 6 may correspond to any of the 0 to n scan chains 508 of FIG. 5. FIG. 5 also shows a block diagram of a test setup 500 for controlling the bus wrapper 150 (see FIG. 3). The test setup 500 shows an example of a configuration that allows data to be loaded into the bus wrapper 150 via scan chains 502 and unloaded from the bus wrapper 150 via the scan chains 508. The scan chains 502 are unique from the scan chains 508. The optional selected scan chain 502 is put in shift mode and used as a conduit for communicating input data to the bus wrapper 150 from the test equipment 520, when it is also in shift mode; the optional selected scan chain 508 is put in shift mode and used as a conduit for communicating output data from the bus wrapper 150 to the test equipment 520. As described earlier, these scan chains can be replaced with primary inputs, primary outputs, compressors, decompressors, serializers, or deserializers. The bus wrapper 150 may also include other of the features shown in FIG. 1, FIG. 3, or in other figures; a description of these features is not provided here for brevity.

The test equipment 520 communicates with the test controller 160 through the test interface 140 (see FIG. 1) using the test signals 141. Alternatively, the test interface 140 may share signals with the functional interface 130 (see FIG. 1).

The test setup 500 includes an input multiplexer 504, an output demultiplexer 506, and the test controller 160. The input multiplexer 504 loads stimulus shift data to the bus wrapper 150 through one of the selected scan chains 502 from the test equipment 520. The output demultiplexer 506 unloads response shift data from the bus wrapper 150 through one of the selected scan chains 508 to the test equipment 520. The test equipment 520 controls the multiplexer 504 via the test controller 160 to select one of the n+1 scan chains 502 to provide stimulus to the integrated circuit 510 through the selected input scan chain. The test equipment 520 controls the demultiplexer 506 via the test controller 160 to select one of the n+1 scan chains 508 to provide the response through the selected output scan chain to the output of the integrated circuit 510. The selected scan chains 502 or 508 may or may not correspond to the cores 110-114 operating on the selected input or output scan chain, being one of the n+1 scan chains 502 or 508. The test equipment 520 may then compare the data unloaded from the bus wrapper 150 and the scan chains 502 and 508 to the data expected from the outputs.

The test controller 160, TAP controller, or controller core may control the multiplexer 504 and the demultiplexer 506 from a data register (DR), from an instruction register (IR), or from any other circuit which is isolated from the active scan chains. The test equipment 520 may control the multiplexer 504 and the demultiplexer 506 using mode control pins, using the test controller 160 via test signals 141 (see FIG. 1), or using the controller core via functional signals 131. The mode control pins may be configured using a Standard Test Interface Language file (“STIL file”). The STIL file may be generated by a compiler tool such as the DFT Compiler™ tool from Synopsys, Inc. The STIL file may be used by a test pattern generation tool such as the TetraMAX™ tool from Synopsys, Inc. or used by tools from a variety of other companies. The test equipment 520 may compile the output from the test pattern generation tool and use it to test the integrated circuit 510.

FIG. 6 is a block diagram showing more details of FIG. 5. A notable feature here is that the bus wrapper 150 is completely bypassable. This is important because it allows the other circuits that have scan to continue to be tested using the traditional approach. The bus wrapper 150 has a bypass around the registers 302, 304, 306 and 308, allowing the integrated circuit 510 to be tested without the bus wrapper 150. For example, the integrated circuit 510 may include a wrapper around each core 110-114, as in many existing devices, in addition to the bus wrapper 150 (which may be described as being around the bus, instead of around an individual core); the bypass structure of FIG. 6 shows that the bus wrapper 150 may be implemented in the integrated circuit 510 without impacting tests directed to the other test structures (not shown). The bus wrapper 150 may include a demultiplexer 602 and a multiplexer 604. The test controller 160 controls the demultiplexer 602 to provide a selected scan chain 502 (see FIG. 5) to either the bus wrapper 150 or bypass it and provide it to a selected scan chain 508, or to other test structures (not shown), in either case, bypassing the bus wrapper 150. If the selected scan chain 502 is provided to the bus wrapper 150 and to the selected scan chain 508, the bus wrapper 150 and scan chains 502 and 508, all process it as described above. If the selected scan chain 502 is provided to selected scan chain 508 or to the other test structures (not shown), the selected scan chains 502 and 508 or other test structures process it without the bus wrapper 150. The test controller 160 controls the multiplexer 604 to provide the output from either the bus wrapper 150 or the selected scan chain 502 to the input of the selected scan chain 508. The test equipment 520 may control the demultiplexer 602 and the multiplexer 604 using a test control register bit.

FIG. 7 is a block diagram of an integrated circuit 700 showing the clock signals that may be implemented in various embodiments. A noteworthy feature is that the arbitrary separation logic 718 is used to control the timing of the asynchronous clocks 722 and 724 in test mode. The integrated circuit 700 may be implemented as part of the integrated circuit 100 (see FIG. 1), the integrated circuit 300 (see FIG. 3), etc. The general operation of the integrated circuit 700 is as follows. In test mode, the clocks provided to the core come from a single source. This can be built into the hardware or separate signals from the test equipment can be synchronized using software. Synchronizing logic controls at what point the clocks are active.

The integrated circuit 700 includes a controller portion 702 and a remote block portion 704, connected via a bus 706. The controller portion 702 may be implemented as part of the test controller 160 (see FIG. 1), the bus wrapper 150 (see FIG. 1 or FIG. 3), etc. The controller portion 702 may be considered a master controller that includes the test controller 160 or the bus wrapper 150 as subcomponents. When operating as a master controller, the controller 702 controls whether the device is operating in functional mode or test mode. The remote block portion 704 may be implemented as part of one of the cores 110-114 (see FIG. 1 or FIG. 3), etc. The bus 706 may correspond to the bus 120 (see FIG. 1 or FIG. 3).

The controller portion 702 may include an address circuit 708, bus keepers 710, a data circuit 712, bus driver circuits 714, a write enable circuit 716, a separation logic circuit 718, a read enable circuit 720, a first clock circuit 722, and a second clock circuit 724. The controller portion 702 receives a first functional clock signal 726 (functional_clk1), a second functional clock signal 728 (functional_clk2), and a test clock signal 730 (test_clk). The controller portion 702 may receive a control signal that selects functional mode or test mode for the device, for example via an interface pin connected to external test equipment or a board. The address circuit 708 corresponds to the address portion 302 (see FIG. 3). The bus keepers 710 are weak drivers that keep the previous state of the bus, with one bus keeper for each bus data bit. The weak drivers drive the previous state until stronger bus drivers switch the bus to a different stat. The data circuit 712 combines the functionality of the data out portion 304 and the data in portion 308 (see FIG. 3).

The remote block portion 704 includes an address decoder circuit 740, AND gates 742, flip-flops 744, enable circuits 746, logic circuits 748, and flip-flops 750.

The integrated circuit 700 operates as follows. The address circuit 708 in the controller portion 702 provides the address information via the bus 706 to the address decoder circuit 740 in the remote block portion 704. The separation logic circuit 718 controls the operational mode (read mode, write mode) of the integrated circuit 700, as well as which clock signal (726, 728 or 730) is provided to the flip-flops 744 and 750. The bus driver circuits 714, as controlled by the write enable circuit 716, provide the data from the data circuit 712 via the bus 706 to the bus keepers 710 and to the AND gates 742 in the remote block portion 704. The flip-flops 744 store the data input to the remote block 704. The logic 748 processes the data stored in the flip-flops 744. The flip-flops 750 store the data output from the logic 748. The enable circuits 746, as controlled by the read enable circuit 720, provide the data from the flip-flops 750 in the remote block portion 704 via the bus 706 to the AND gates 742, to the bus keepers 710 in the controller portion 702, and to the data circuit 712. To reduce power the clock signals 722 and 724 may also be gated with AND gates 742 using glitch free clock enable circuitry.

FIG. 8 is a block diagram of an integrated circuit 800 showing more detail of the read enable operation. In the circuit 800, the BUS_ON bit (signal) is used to provide an autonomous way to control bus activity during test mode. The circuit 800 includes numerous logic elements, multiplexers and flip-flops, connected as shown in FIG. 8. For the read enable operation, test_enable 802 selects between either the functional read enable signal 804 (functional_read_en) (or the functional read clock) or the bus wrapper read enable signal 806 (BUS_READ_EN) (or the bus wrapper read clock). Then the scan_en signal 808 selects between either the read enable control bit 806 when not scanning (or not shifting) and “0” when shifting. Setting the scan enable signal scan_en 808 to “1” forces “0” when shifting, which prevents all the remote cores 110 through 114 from writing to the bus. The BUS_READ_EN register 810 can be programmed by the ATPG tool through the scan_in0 signal 812. This value can be changed under certain conditions. For example, a BUS_ON bit 814 may optionally detect that the bus is active and disable modification of BUS_READ_EN 806 in capture mode until the next cycle. Thus, preventing any collision of the write and read operations by ensuring a minimum of 1 clock cycle between write and read operations. If present, BUS_EN_CNT 916 (see FIG. 9), an optional down counter, and BUS_EN_MAX, an optional recirculating storage register, can be programmed by the ATPG tool using one or more scan inputs. The down counter then counts down each clock cycle until it reaches zero. During the countdown process, the read enable bit 806 retains its state using a recirculating cell made up of the scan register 810 and the multiplexer (mux) 818. When the counter BUS_EN_CNT 916 reaches zero (shown here as BUS_EN_CNT==0 816), the read enable signal 806 changes state, becoming the opposite state of the write enable, either active or inactive. If it becomes active, the enable signal 806 (or a clock 821) is sent to the cores 110 through 114. If it becomes inactive, the enable signal 806 is deactivated at (or a clock is not sent to) the cores 110 through 114. The value of BUS_EN_CNT 916 is then reset to BUS_EN_MAX. The timing diagram for these operations is shown in FIG. 9. Alternatively, this same process can be performed with an up counter.

The flip-flop 824 and related circuit elements implement what may be referred to as a bus enable monitor circuit 828. The bus enable monitor circuit 828 monitors the bus enable signals and not the bus directly. The bus on (BUS_ON) signal 826 is set when the bus 120 (see FIG. 1, FIG. 3, etc.) is in use by the controller core (e.g., the test controller 160 of FIG. 1) or any of the cores 110-114. The bus read enable signal (BUS_READ_EN) 806 and the bus data enable signal (BUS_DATA_EN) 822 are used as inputs to the bus monitor circuit 828.

The recirculating cell 832 includes two multiplexers and a flip-flop. The recirculating cell 832 is similar to the recirculating cell 400 of FIG. 4. Also, the multiplexers 811 and 818, and the flip-flop 810, form a recirculating cell for the bus read enable signal BUS_READ_EN 806.

FIG. 9 shows timing diagrams for the signals shown in FIG. 8. More specifically, FIG. 9 shows an example of the timing of BUS_ON 814 in relation to the enable signals 806 and 822. An interesting feature is the reloadable counter that is loaded in test shift mode and in test capture mode controls the timing of test specific circuitry like that related to BUS_ON 814. The BUS_EN_CNT signal 916 starts at the maximum set by BUS_EN_MAX, which is 3 in the example of FIG. 9. At time t1, BUS_ON 814 goes high and BUS_READ_EN 806 goes low. BUS_EN_CNT 916 counts down at t2, t3 and t4. At t4, BUS_EN_CNT 916 is zero, so BUS_EN_CNT==0 816 in FIG. 8 is true. At t5, BUS_READ_EN 806 goes high, BUS_EN_CNT 916 is reset to the maximum, and BUS_ON 814 goes low. At t6, BUS_ON 814 goes high, and BUS_DATA_EN 822 goes low. BUS_EN_CNT 916 counts down at t7, t8 and t9. At t10, BUS_ON 814 goes low, and BUS_DATA_EN 822 goes high.

FIG. 10 is a block diagram of a circuit 1000 showing more details for the write enable operation. The circuit 1000 includes a pipeline 1002 that has a number of flip-flops (also referred to as registers) and associated multiplexers, connected in series. A noteworthy feature here is that the pipeline 1002 is loaded in test shift mode and can be arbitrarily modified during test capture mode. The arbitrary modification shown here is recirculation. The circuit 1000 includes a number of signals in common with FIGS. 8-9 and they are numbered similarly (e.g., the test_enable signal 802). The pipeline 1002 controls the sequence of enabling and disabling the bus drivers and can occur in any order and any number of times. The pipeline 1002 may be used in place of the recirculating register (address cell 400) of FIG. 4. The configuration of the pipeline 1002 can be used for any of the other bus wrapper signals including address, data, and read enable.

The pipeline 1002 is a recirculating pipeline. Alternatively, the pipeline 1002 (or any of the recirculating cells discussed above with reference to FIG. 4) may be replaced with a pure (non-recirculating) pipeline.

The signals BUS_DATA_INTERNAL may be derived from the functional signals 131 (see FIG. 1) and the functional interface 130. The signals BUS_DATA_INTERNAL come from an arbitrary location, for example from internal to the device or external to the device.

Of particular note are the multiplexers 1004, 1006, 1008 and their related inputs, outputs and connections. The multiplexer 1004 receives an output from the last register of pipeline 1002 and an arbitrary input, and outputs a selected one of the output from the last register and the arbitrary input, according to the scan enable signal scan_en 808. The multiplexer 1006 receives the output from the multiplexer 1004 and a scan input, and outputs to the first register of the pipeline 1002 a selected one of the scan input scan_in3 and the output of the multiplexer 1004, according to the scan enable signal scan_en 808. The multiplexer 1008 receives the output of the multiplexer 1004 and a functional input (BUS_DATA_EN_FUNCTIONAL here), and outputs a selected one of the functional input and the output of the multiplexer 1004, shown here as the bus data enable signal BUS_DATA_EN 822, to the bus control circuitry input, according to the test_enable signal test_enable 802.

FIG. 11 is a block diagram of a circuit 1100. The circuit 1100 may be used to form each element of the address portion 302 (see FIG. 3) of the bus wrapper 150. An interesting feature here is the use of a recirculating cell to control the address bus (e.g., the address lines in the bus 120 of FIG. 3) during test mode. The cell is loaded during test shift mode and maintains its state during the test capture mode. A pipeline with arbitrary modification logic, such as recirculation, could also be used to control the address during test capture mode.

The circuit 1100 implements an address cell (similar to the recirculating cell 400 of FIG. 4) with the addition of test_enable signal 802 and scan enable signal 808. The circuit 1100 includes a number of signals in common with FIGS. 8-10 and they are numbered similarly (e.g., the scan_clk signal 821). Again, for example, the address portion 302 with four outputs may be implemented using four of the circuits 1100.

The recirculating cell utilized in FIG. 11 allows the cell to be programmed in a fixed state for test purposes using the scan_wrapper signal 1102. If scan_wrapper 1102 is low, test_enable 802 is low, and scan_en 808 is low, the normal functional address (shown here as BUS_ADDRESS_internal [i] 1112) is driven directly to the bus 120 (see FIG. 1; shown here as BUS_ADDRESS [i] 1108). If scan_wrapper 1102 is high, the address is controlled to a fixed state, in this case high, although with slight modifications this could be any value. This includes an option to feedback the value from the recirculating cell 1104 directly to scan_wrapper 1102. If test_enable 802 is high, the value of the recirculating cell 1104 (shown here as BUS_ADDRESS_REG [i] 1110) is driven to the bus 120 (shown here as BUS_ADDRESS [i] 1108). If scan_en 808 is low, the recirculating cell 1104 goes into its recirculating state, and its output value BUS_ADDRESS_REG [i] 1110 is loaded back in. If scan_en 808 is high, the recirculating cell 1104 gets its input from the scan chains (shown here as scan_in [i] 1106).

FIG. 12 is a block diagram of a circuit 1200 showing a cell for bus data. The circuit 1200 may be used to form the elements of the data in portion 308 (see FIG. 3) and the data out portion 304 of the bus wrapper 150. A noteworthy feature here is that the bus wrapper 150 can be used as a test point for testing the functional controller, including the functional interface 130 and associated logic.

Many of the signals in FIG. 12 correspond to the signals used in other figures, and are shown here with the same labels (e.g., the test_enable signal 802). In FIG. 12, each j represents a different bit of the data bus. The width of the bus is the maximum value of j, if counting from one. The signal bus_data_out [j] 1202 is the jth functional data output from the controller core (e.g., the test controller 160 of FIG. 1). It can go back to the controller core for use elsewhere (shown here as some_data_in [j] 1204), to the bus 120 (shown here as BUS_DATA_FUNCTIONAL[j] 1206), or it can be exclusive or'd (e.g., with the XOR gate 1226) with the other bits, and then stored as a test point (shown here as TEST_POINT_BUS_DATA_OUT 1208). The signal other_data_en 1210 controls a mux 1212 which selects between input data from the bus 120 (bus_data_in_test [j]) and arbitrary data (other_data_out[j]) from an arbitrary source with an arbitrary purpose. The selected signals (other_data_in [j]) are then sent to an arbitrary destination (e.g. the master controller, distinct from the test controller 160 of FIG. 1). The test_enable signal 802 controls a mux 1214 that controls whether bus_data_en_functional 1216 or bus_data_en_reg 1218 is selected. This controls whether the functional enable signal 1216 enables the bus or the bus wrapper enable signal 1218 controls the bus (using the signal bus_data_en 822 as shown). The test_enable signal 802 controls another mux 1220 that selects either bus_data_out [j] 1202 or BUS_DATA_REG_OUT [j] 1222. Thus, controlling whether output data comes from an arbitrary location, which may be within the controller core, or from the bus wrapper 150 Data Out 304 (see FIG. 3). A tristatable driver (see the data circuits 314 in FIG. 3) may drive the bus 120 (see FIG. 3), shown here as the signals BUS_DATA[j]. In this example, the bus is tristatable. However, other configurations may implement a similar configuration with a non-tristable bus. A BUS_DATA_HOLDER 1224 (cf. the bus keepers 710 of FIG. 7), which is a weak driver, keeps the last state of the bus 120 when it isn't driven by anything else. This drives the data input. In this case each signal BUS_DATA [j] is NAND'd with reset. So, when reset is high, the bus data coming in (BUS_DATA_IN [j]) is forced to an arbitrary value, in this case low, for each of the j data bits. Replacing the NAND gate with an AND gate results in a high being driven to the bus. Each BUS_DATA_IN [j] bit is sent to both a storage register for each of the j bits (shown here as BUS_DATA_REG_IN [j]) and elsewhere in the controller core. The scan_en signal 808 controls a mux 1228 that selects either a fixed input value or scan_in [j] 1252. The output from the mux 1228 goes to TEST_POINT_BUS_DATA_IN_OUT [j]. The scan_wrapper signal 1102 controls a mux 1230 that selects either TEST_POINT_BUS_DATA_IN_OUT [j] or the data from the bus 120 (BUS_DATA_IN [j]). This allows for the setting of the data inputs to the controller core to a fixed value for test purposes or to the value of the bus wrapper 150 Data In 308 or to an arbitrary fixed value, shown here as a one. The actual input storage bits are the same as those shown in FIG. 8. The flip-flop 1232 and the mux 1230 uses a similar recirculating cell used to drive the address lines of the bus 120 as shown in FIG. 4. In FIG. 3, the bus wrapper 150 is shown with separate Data Out 304 and Data In 308. However, to save space, they can be combined. All these cells are arbitrarily daisy chained, as previously described, with the scan_in signals 1252 as inputs to and the Q signals as outputs of each flip-flop 1232. In other words, within the number of daisy chains and the order within each daisy chain is completely arbitrary. However, some tools prefer a certain order, but this is tool dependent.

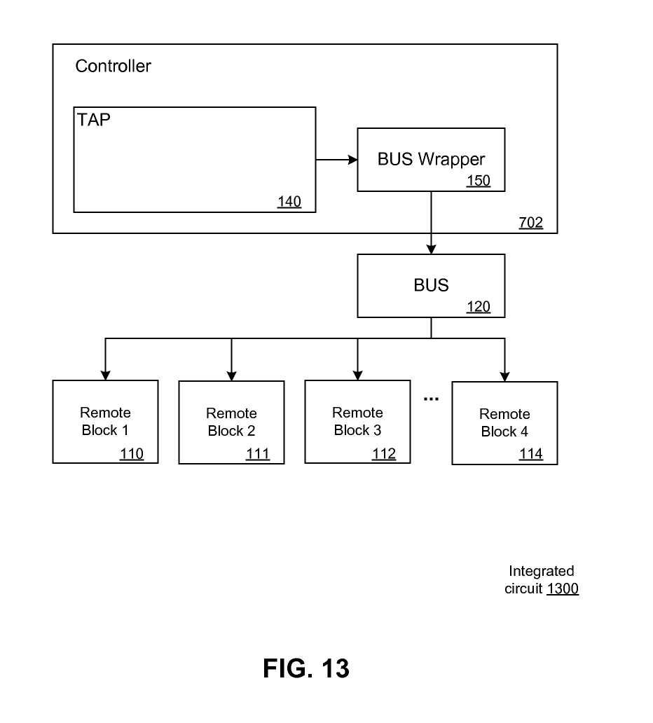

FIG. 13 is a block diagram of an integrated circuit 1300. The circuit 1300 is an alternative arrangement for the integrated circuit 100 (see FIG. 1) or the integrated circuit 700 (see FIG. 7). In the circuit 1300, the test interface 140 (e.g., a TAP 140 as shown here) and the bus wrapper 150 are components of the controller 702 (see FIG. 7). (The controller 702 may be considered to be distinct from the test controller 160 of FIG. 1 in that the controller 702 includes the functional interface 130 and may include other, additional or fewer cores.) The integrated circuit 1300 also includes the bus 120 and remote blocks (cores) 110, 111, 112, 113 (not shown) and 114, similar to those elements in FIG. 1. The operation of the integrated circuit 1300 is similar to that of integrated circuit 100 as described above.

The figures that show the circuit details (e.g., FIGS. 4, 8, 10-12, 14-17) may be considered to be components of the controller 160 (see also FIG. 1) and, at a lower level, components of the bus wrapper 150 (see also FIG. 3).

FIG. 14 is a block diagram of an integrated circuit 1400. The circuit 1400 may be used to form elements of the enable portion 306 (see FIG. 3) of the bus wrapper 150. A noteworthy feature here is that the read enable signal BUS_READ_EN 806 is loadable in test shift mode and controlled by a counter in test capture mode. The counter is loadable in test shift mode and in test capture mode, counts down to zero. When it reaches zero, it is loaded with the value BUS_EN_CNT_MAX stored in the multiplexers 1402. BUS_EN_CNT_MAX is loadable in test shift mode and in test capture mode, and in test mode it recirculates to hold its value. Another noteworthy features is that the BUS_READ_EN signal 806 recirculates until BUS_EN_CNT is zero and BUS_ON 814 is zero. In other words, the bus enable counter has reached zero and the bus is inactive for at least one cycle.

In general, the circuit 1400 generates an enable signal that controls whether the bus 120 (see FIG. 1) is enabled or not enabled. The enable signal may be a read enable signal that controls whether the bus 120 is read enabled or not read enabled. The enable signal may be a write enable signal that controls whether the bus 120 is write enabled or not write enabled. Alternatively, the write enable signal may be the inverse of the read enable signal. Alternatively, the circuit 1400 may generate a write enable signal with an inverse read enable signal. Alternatively, the circuit 1400 may generate a write enable signal with no read enable signal. Alternatively, the circuit 1400 may generate a read enable signal with no write enable signal. The alternative chosen depends on the application.

The circuit 1400 generates the read enable signal 806 (BUS_READ_EN) and the bus enable counter signal 916 (BUS_EN_CNT) used in FIGS. 8-9 and other figures, including the timing shown in FIG. 9. The read enable signal 806 determines whether the bus is read enabled or not read enabled. The maximum value, BUS_EN_CNT_MAX[n], for the bus enable counter 916 is stored in the flip-flops 1402, which may be programmed via the scan_in[n] signal 1452. The flip-flops 1404 store the current value of BUS_EN_CNT 916. If BUS_EN_CNT 916 is not zero, box 1406 decrements BUS_EN_CNT 916 by one (see also FIG. 9). If BUS_EN_CNT 816 is zero (e.g. in FIG. 8, BUS_EN_CNT==0 816 is true), box 1408 and the related circuitry cause BUS_READ_EN 806 to go high (as shown in FIG. 9 at t5).

The flip-flops 1402 may be omitted in designs in which it is not desired to include a programmable maximum value for the enable counter. In such a case, the maximum value may be hard-coded and loaded into the flip-flops 1404 when the counter is reset.

The recirculating cell 1410 for the bus read enable signal BUS_READ_EN 806 includes two multiplexers and a flip-flop. (Compare to the recirculating cell 400 of FIG. 4.) Also in FIG. 14, the flip-flops 1402 (also referred to as the max value registers or the start value registers) and the associated multiplexers form a recirculating cell 1412 for the bus enable counters.

Although the circuit 1400 is shown generating the read enable signal (BUS_READ_EN 806), similar circuits may be used to control the timing on other of the signals of the bus wrapper 150, including the clock signals. (An example for the bus clock counter is shown in FIG. 17 below.)

FIG. 15 is a block diagram of an integrated circuit 1500. The circuit 1500 forms elements of the data in portion 308 (see FIG. 3) of the bus wrapper 150. An interesting feature here is that the latch circuit 1502 provides an extra half cycle of delay, which can be used to control the timing of the data signals. FIG. 15 also shows the recirculating cell 1509 which includes the register 1508 and multiplexers 1504 and 1506. Another interesting feature shown here is that the data in portion 308 and the data out portion 304 are sharing the same storage register 1508 via the multiplexer 1504 controlled by scan_en 808 and read_en 806.

The circuit 1500 generally implements a latch for the bus data input signal (bus_data_in) 1510. For example, the circuit 1500 may be used to implement the data in portion 308 (see FIG. 3), with the bus_data_in signal 1510 corresponding to the signals received via the bus 120. The latch 1502 receives the bus data latch input signal (bus_data_latch_in), and outputs the bus data latch output signal (bus_data_latch_out[j]). The latch 1502 may be modeled as a flip-flop during ATPG pattern generation, and provides an extra delay for the data being read from remote cores 110 through 114. The mux 1512 selectively provides the bus_data_in signal 1510 or an arbitrary fixed value shown as “0” to the flop-flop 1502 as the bus data latch input signal (bus_data_latch_in[j]). The mux 1514 selectively provides the bus_data_in signal 1510 or the bus_data_latch_out[j] signal, as the bus data input signal (bus_data_in[j]), to the mux 1504. The mux 1504 selects between the bus data output signal (bus_data_out[j]) 1202 and the bus_data_in[j] signal, and outputs the bus data signal (bus_data[j]). The mux 1506 selects between the bus_data[j] signal and the scan input signal (scan_in[j]) 1552, according to the scan enable signal (scan_en) (not shown, but labeled 808 in other figures). The flip-flop 1508 stores the output of the mux 1506 for feeding back to the mux 1504 as the bus_data_out[j] signal 1202. Note that the multiplexers 1504 and 1506, and the flop-flop 1508, form a recirculating cell 1509 as shown in FIG. 4. Also, the multiplexers 1512 and 1520, and the flip-flop 1522, form a recirculating cell for the bus data latch enable signal bus_data_latch_en.

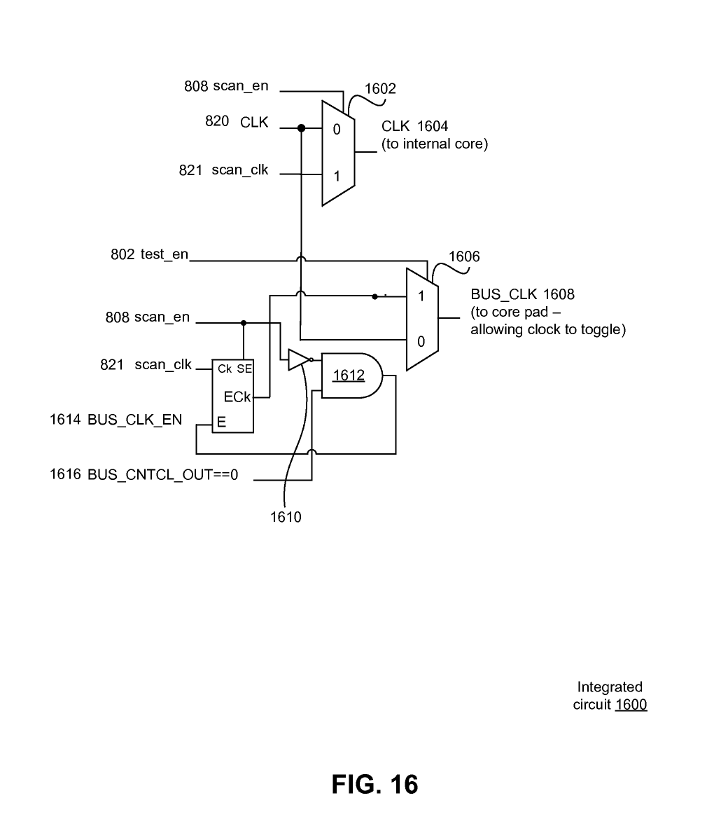

FIGS. 16-18 relate to the bus clock signal BUS_CLK 1608 and related signals (e.g., the clock signals 722 and 724 in FIG. 7). FIG. 16 is a block diagram of an integrated circuit 1600. The circuit 1600 forms elements of the Clock 1 722 portion (see FIG. 7) of the bus wrapper 150 (see FIG. 1). A noteworthy feature here is that an arbitrary signal, in this case a clock counter stored in the flip-flops 1706 (see FIG. 17), is used to determine when write clocks are sent to the remote cores 110-114 (see FIG. 1).

The circuit 1600 generates the BUS_CLK clock signal 1608. The circuit 1600 operates on a number of signals that appear in other figures, and the same labels are used here (e.g., the scan_en signal 808). The mux 1602 selects between the CLK signal 820 and the scan_clk signal 821 according to the scan_en signal 808 (or, alternatively, test_en 802), for output as the CLK signal 1604 to the internal core (e.g., controller 702, which includes the functional interface 130 and is distinct from the remote cores 110-114 of FIG. 1). The mux 1606 selects between the CLK signal 820 and the scan_clk signal 821 according to the test_en signal 802, for output as the BUS_CLK signal 1608 to the core pad, one of the clocks 722 or 724, allowing the clock to toggle. FIG. 17 provides further details of how the NOT circuit 1610 and the AND circuit 1612 generate, using the output from 1708, the BUS_CNTCL_OUT signal 1716.

FIG. 17 is a block diagram of an integrated circuit 1700. The circuit 1700 forms elements of the Clock 1 722 portion (see FIG. 7) of the bus wrapper 150 (see FIG. 1). A noteworthy feature here is that the flip-flops 1706 implementing clock counters are loadable in test shift mode and in test capture mode, and count down to zero. When each reaches zero, it is loaded with the corresponding value stored in the flip-flops 1702, BUS_CNT_CLK_MAX [m] 1704. BUS_CLOCK_CNT_MAX [m] 1704 is loadable in test shift mode and in test capture mode, and in test mode recirculates to hold its value.

The signals scan_in [m] 1752 and scan_in [n] 1754 provide scan inputs to the circuit 1700. For example, m goes from 1 to M, where M is the width of the clock counter. The circuit 1700 provides more detail regarding how the circuit elements generate the bus clock enable signal BUS_CLK_EN 1614 using the output from the flip-flop 1706, the BUS_CNTCL_OUT [m] signal 1716 (see also the BUS_CNTCL_OUT==0 signal 1616 in FIG. 16). The bus clock enable signal 1614 controls whether the bus clock is enabled or not enabled. The flip-flops 1702 store BUS_CNT_CLK_MAX[m] 1704, which is the maximum (starting) value for the bus counter clock. The flip-flops 1706 store BUS_CNTCL_OUT[m], which is the current value for each bus counter clock. The output from the NOR gate 1708 is “one” if the corresponding bus counter clock register is zero (BUS_CNT_CLK_OUT==0 [0:m] as shown). If so, the mux 1710 selects BUS_CNT_CLK_MAX[m] 1704 to be loaded into the corresponding one of the bus counter clock registers 1706 from BUS_CNTCL_IN[m] 1712. If not, the block 1714 decrements the bus counter clock by one (BUS_CNT_CLK_OUT−1 [0:m] as shown). Note that the circuits implementing the circuit block 1708 may be adjusted according to the width of the BUS_CNTCL_OUT registers 1706; in this example, the width is 2.

The recirculating cell 1720 for the bus count clock start value BUS_CNT_CLK_MAX[m] 1704 includes the flip-flops 1702 and the associated multiplexers 1710 and 1711.

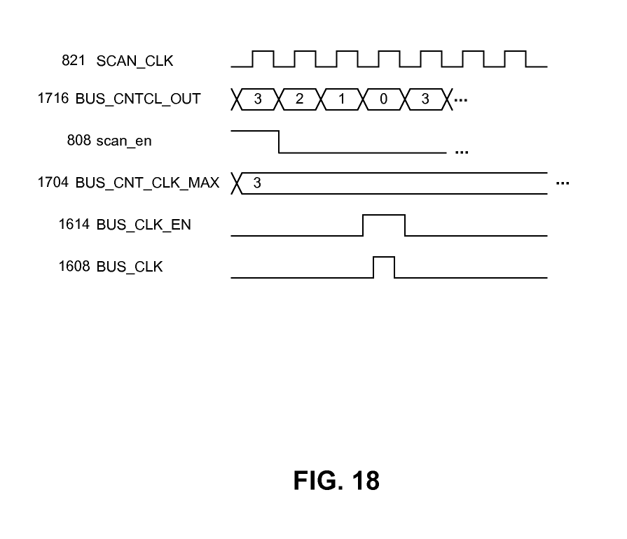

FIG. 18 shows timing diagrams for the signals shown in FIGS. 16-17. A noteworthy feature here is the reloadable counter that is loaded in test shift mode, and in test capture mode counts down with each clock signal issued. When scan_en 808 goes low, BUS_CNTCL_OUT 1716, the output from 1706, begins decrementing. When BUS_CNTCL_OUT 1716 reaches zero, BUS_CLK_EN 1614 goes high, which enables BUS_CLK 1608.

Note that, to avoid clutter in the figures, certain signals are omitted when their presence is clear from the context or other figures. For example, unless otherwise specified, all multiplexers with the scan input signal (e.g., scan_in, scan_in3, scan_in4, etc.) have the scan enable signal (scan_en) 808 as a select line, where scan_in is selected when scan_en 808 is high (logic “1”). See, e.g., numerous multiplexers in FIG. 8, the multiplexer 1506 in FIG. 15, etc.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations and equivalents may be employed without departing from the scope of the present disclosure as defined by the claims.

What is claimed is:

1. An integrated circuit, comprising:
a plurality of cores;
a bus that connects between the plurality of cores, wherein the bus selectively operates in one of a functional mode and a test mode, according to the integrated circuit operating in one of the functional mode and the test mode;
a functional interface that receives a plurality of functional inputs from outside of the integrated circuit, that provides the plurality of functional inputs to the bus, and that receives a plurality of functional outputs from the bus, when the integrated circuit is operating in the functional mode;
a test interface that receives a plurality of test inputs from outside of the integrated circuit, and that provides a plurality of test outputs to the outside of the integrated circuit, when the integrated circuit is operating in the test mode; and
a bus wrapper that connects between the test interface and the bus.

2. The integrated circuit of claim 1, wherein in the test mode, the bus wrapper receives the plurality of test inputs from the test interface and provides the plurality of test inputs to the bus, and
wherein in the test mode, the plurality of cores receives the plurality of test inputs from the bus.

3. The integrated circuit of claim 1, wherein in the test mode, the plurality of cores generates the plurality of test outputs from the plurality of test inputs, and provides the plurality of test outputs to the bus, and
wherein in the test mode, the bus wrapper receives the plurality of test outputs from the bus.

4. The integrated circuit of claim 1, wherein in the test mode, the bus wrapper receives the plurality of test inputs from the test interface and provides the plurality of test inputs to the bus,
wherein in the test mode, the plurality of cores receives the plurality of test inputs from the bus, generates the plurality of test outputs from the plurality of test inputs, and provides the plurality of test outputs to the bus, and
wherein in the test mode, the bus wrapper receives the plurality of test outputs from the bus.

5. The integrated circuit of claim 1, wherein in the test mode, the bus wrapper receives the plurality of test inputs from the test interface and provides the plurality of test inputs to the bus,
wherein in the test mode, the plurality of cores receives the plurality of test inputs from the bus, generates the plurality of test outputs from the plurality of test inputs, and provides the plurality of test outputs to the bus, and
wherein in the test mode, the plurality of cores receives the plurality of test outputs from the bus and generates a second plurality of test outputs from the plurality of test outputs.

6. The integrated circuit of claim 1, wherein in the functional mode, the plurality of cores receives the plurality of functional inputs from the bus, generates the plurality of functional outputs, and provides the plurality of functional outputs to the bus.

7. The integrated circuit of claim 1, wherein in the test mode, the bus is disabled prior to the bus wrapper receiving the plurality of test inputs, and the bus is enabled prior to the bus wrapper providing the plurality of test inputs to the bus.

8. The integrated circuit of claim 1, wherein the bus wrapper comprises a plurality of cells, wherein each cell comprises:
a first multiplexer that receives a recirculating input and a scan input, and that outputs a first output corresponding to a selected one of the scan input and the recirculating input;
a register that receives the first output and that outputs a second output corresponding to the first output, wherein the first multiplexer receives the second output as the recirculating input; and
a second multiplexer that receives the second output and a functional input, and that outputs a third output corresponding to a selected one of the second output and the functional input as selected by a test enable signal.

9. The integrated circuit of claim 1, wherein the bus wrapper includes a pipeline, wherein the pipeline includes:
a plurality of registers connected in series, wherein an output of one of the plurality of registers is connected to an input of another of the plurality of registers;
a first multiplexer that receives an output from a last register of the plurality of registers and an arbitrary input, and that outputs a first multiplexer output corresponding to a selected one of the output from the last register and the arbitrary input;
a second multiplexer that receives the first multiplexer output and a scan input, and that outputs a second multiplexer output corresponding to a selected one of the scan input and the first multiplexer output to a first register of the plurality of registers; and
a third multiplexer that receives the first multiplexer output and a functional input, and that outputs a third multiplexer output corresponding to a selected one of the functional input and the first multiplexer output to the bus control circuitry input as selected by a test enable signal.

10. The integrated circuit of claim 1, wherein the bus wrapper includes a counter circuit that generates an enable signal and that controls the bus using the enable signal, wherein the enable signal controls whether the bus is enabled or not enabled.

11. The integrated circuit of claim 1, wherein the bus wrapper includes a counter circuit that generates a bus clock enable signal and that controls the bus using the bus clock enable signal, wherein the bus clock enable signal controls whether the bus clock is enabled or not enabled.

12. The integrated circuit of claim 1, further comprising a test controller, wherein the test controller includes the bus wrapper, and wherein the test controller includes:
a data circuit that stores data;
a write enable circuit that controls outputting the data from the data circuit to the bus;
a read enable circuit that controls inputting the data from the bus to the data circuit; and
separation logic that controls the write enable circuit and the read enable circuit.

13. The integrated circuit of claim 1, wherein the bus wrapper includes a data in portion, wherein the data in portion includes:
a first multiplexer that receives a bus data input signal and that selectively outputs a bus data latch input signal;
a latch that receives the bus data latch input signal and that outputs a bus data latch output signal;
a second multiplexer that receives the bus data input signal and the bus data latch output signal, and that selectively outputs a second bus data input signal;
a third multiplexer that receives the second bus data input signal and a bus data output signal, and that selectively outputs a bus data signal;
a fourth multiplexer that receives the bus data signal and a scan input signal, and that selectively outputs a flip-flop input signal; and
a flip-flop that receives the flip-flop input signal and that outputs the bus data output signal.

14. The integrated circuit of claim 1, wherein the bus wrapper includes a bus enable monitor circuit, wherein the bus enable monitor circuit includes:
a logic circuit that receives a bus read enable signal and a bus data enable signal, and that generates an output signal; and
a flip-flop that receives the output signal, wherein the flip-flop outputs a bus on signal that is set when the bus is in use.

15. The integrated circuit of claim 1, further comprising:
a master controller that controls the integrated circuit to selectively operate in one of the functional mode and the test mode.

16. The integrated circuit of claim 1, further comprising:
a test controller that controls the integrated circuit to selectively operate in one of a test shift mode and a test capture mode.

17. The integrated circuit of claim 1, wherein the bus wrapper includes an enable portion, the integrated circuit further comprising:
a test controller, coupled to the test interface and to the bus wrapper, that controls the enable portion to selectively operate in one of an output enable mode and an input enable mode,
wherein in the output enable mode, the bus wrapper provides the plurality of test inputs to the bus, and
wherein in the input enable mode, the bus wrapper receives the plurality of test outputs from the bus.

18. The integrated circuit of claim 1, wherein the bus wrapper includes an address portion, a data out portion, an enable portion, and a data in portion, the integrated circuit further comprising:
a test controller, coupled to the test interface and to the bus wrapper, that serially receives the plurality of test inputs from the test interface, and that provides the plurality of test inputs to the address portion and to the data out portion,
wherein the test controller controls the enable portion to selectively operate in one of an output enable mode and an input enable mode, wherein in the output enable mode, the address portion and the data out portion provide the plurality of test inputs to the bus,
wherein a selected core of the plurality of cores receives the plurality of test inputs from the bus and provides the plurality of test outputs to the bus,
wherein in the input enable mode, the data in portion receives the plurality of test outputs from the bus, and
wherein the test controller serially provides the plurality of test outputs from the data in portion to the test interface.

19. A method of testing an integrated circuit, comprising:
providing the integrated circuit, wherein the integrated circuit has a plurality of cores, a bus, a functional interface, a test interface, and a bus wrapper, wherein the bus connects between the plurality of cores, and wherein the bus wrapper connects between the test interface and the bus;
selectively operating the bus in one of a functional mode and a test mode, according to the integrated circuit operating in one of the functional mode and the test mode;
when the integrated circuit is operating in the functional mode:
receiving, by the functional interface, a plurality of functional inputs from outside of the integrated circuit,
providing, by the functional interface, the plurality of functional inputs to the bus, and
receiving, by the functional interface, a plurality of functional outputs from the bus; and
when the integrated circuit is operating in the test mode:
receiving, by the test interface, a plurality of test inputs from outside of the integrated circuit, and
providing, by the test interface, a plurality of test outputs to the outside of the integrated circuit.

20. An integrated circuit, comprising:
core means for receiving a plurality of inputs, for processing the plurality of inputs, and for generating a plurality of outputs;
bus means for connecting between the core means, and for selectively operating in one of a functional mode and a test mode, according to the integrated circuit operating in one of the functional mode and the test mode;
functional interface means for receiving a plurality of functional inputs from outside of the integrated circuit, for providing the plurality of functional inputs to the bus means, and for receiving a plurality of functional outputs from the bus means, when the integrated circuit is operating in the functional mode;
test interface means for receiving a plurality of test inputs from outside of the integrated circuit, and for providing a plurality of test outputs to the outside of the integrated circuit, when the integrated circuit is operating in the test mode; and
bus wrapper means for connecting between the test interface and the bus.
